(19) United States
(12) Patent Application Publication
(10) Pub. No.: US 2026/0110073 A1
(43) Pub. Date: Apr. 23, 2026

(54) MASK STAGE, DEPOSITION APPARATUS INCLUDING THE SAME, AND ELECTRONIC DEVICE MANUFACTURED BY USING THE SAME

(71) Applicant: Samsung Display Co., Ltd., Yongin-si, Gyeonggi-do (KR)

(72) Inventor: Jin Yong LEE, Yongin-si (KR)

(21) Appl. No.: 19/232,172

(22) Filed: Jun. 9, 2025

(30) Foreign Application Priority Data
Oct. 18, 2024 (KR) 10-2024-0142905

(51) Int. Cl. C23C 14/04; H10K 59/12; H10K 71/16

(52) U.S. Cl. CPC C23C 14/042; H10K 59/1201; H10K 71/166

(57) ABSTRACT

A mask stage, a deposition apparatus including the mask stage, and an electronic device manufactured by utilizing the mask stage are disclosed. The mask stage may include a lattice support that supports a deposition mask and has a plurality of lattice holes, and a mask chuck that is around (e.g., surrounds) the lattice support and supports an edge portion of the deposition mask. The deposition mask may be made of a non-magnetic material, and the lattice support may be made of a ferromagnetic material.

### CROSS-REFERENCE TO RELATED APPLICATION

The present application claims priority to and the benefit of Korean Patent Application No. 10-2024-0142905, filed on Oct. 18, 2024, in the Korean Intellectual Property Office, the entire disclosure of which is incorporated herein by reference.

### BACKGROUND

### 1. Field

One or more embodiments of the present disclosure relate to a mask stage, a deposition apparatus including the mask stage, and an electronic device manufactured by utilizing the mask stage.

### 2. Description of the Related Art

Wearable devices in which a focus is formed at a distance close to the user's eyes have been developed in the form of glasses and/or a helmet. For example, the wearable devices may include a head mounted display (HMD) device and/or augmented reality (hereinafter, referred to as “AR”) glasses. The wearable devices may provide an AR screen and/or a virtual reality (hereinafter, referred to as “VR”) screen to a user.

In the case of wearable devices, such as the HMD device and/or the AR glasses, a display specification of about 3000 pixels per inch (PPI) or higher is desired or required to allow users to use them for a long time without symptoms of dizziness. To this end, organic light emitting diode on silicon (OLEDoS) technology is emerging for use in a high-resolution small organic light emitting display device. The OLEDoS is a technology in which organic light emitting diodes (OLED) are disposed or provided on a semiconductor substrate on which complementary metal oxide semiconductor (CMOS) elements are disposed or provided.

In order to manufacture a display panel having a high resolution of about 3000 PPI or higher, a high-resolution deposition mask is desired or required. For example, the deposition mask may be manufactured by forming or providing a membrane having a plurality of pixel openings on a substrate, such as a silicon wafer, and partially etching the substrate to form or provide cell openings that expose the pixel openings.

In a deposition process to form or provide organic light emitting layers on a backplane substrate, the backplane substrate may be disposed or provided on the deposition mask, and an organic material may be deposited on the backplane substrate through the pixel openings of the deposition mask. However, if (e.g., when) the deposition mask is manufactured by utilizing the silicon wafer, the deposition mask may sag down due to its own weight during the deposition process, which may increase the gap between the backplane substrate and the membrane and may also cause misalignment between electrode patterns on the backplane substrate and the organic light emitting layers.

### SUMMARY

One or more aspects of embodiments of the present disclosure are directed toward a mask stage capable of preventing sagging of a deposition mask (or reducing a degree or occurrence of sagging of a deposition mask), a deposition apparatus including the mask stage, and an electronic device manufactured by utilizing the mask stage.

However, embodiments of the present disclosure are not limited to those set forth herein. The above and other aspects and features of certain embodiments of the present disclosure will become more apparent to one of ordinary skill in the art to which the present disclosure pertains by referencing the detailed description of the present disclosure given.

One or more aspects of embodiments of the present disclosure are directed toward a mask stage. The mask stage may include a lattice support that supports a deposition mask and has a plurality of lattice holes, and a mask chuck that is around (e.g., surrounds) the lattice support and supports an edge portion of the deposition mask. The deposition mask may be made of a non-magnetic material, and the lattice support may be made of a ferromagnetic material.

According to one or more embodiments of the present disclosure, the deposition mask may include a mask frame that has a plurality of cell openings and includes a rib region that defines the plurality of cell openings, and a membrane that has a plurality of pixel openings to communicate with the plurality of cell openings and is disposed or provided on the mask frame.

According to one or more embodiments of the present disclosure, the lattice support may support the rib region, and the plurality of lattice holes may communicate with the plurality of cell openings.

According to one or more embodiments of the present disclosure, the lattice support may include a plurality of protrusions, and the rib region may be supported by the plurality of protrusions.

According to one or more embodiments of the present disclosure, the lattice support may be made of ferritic stainless steel, martensitic stainless steel, precipitation hardening stainless steel, and/or an invar alloy.

According to one or more embodiments of the present disclosure, the mask chuck may include an electrostatic electrode to provide an electrostatic force to hold the edge portion of the deposition mask.

One or more aspects of embodiments of the present disclosure are directed toward a deposition apparatus. The deposition apparatus may include a deposition source to provide a vapor deposition material, a mask stage above the deposition source and on which a deposition mask is placed or provided, and a substrate chuck that is above the mask stage and supports a substrate to be opposite to (e.g., face) the deposition mask. The mask stage may include a lattice support that supports the deposition mask and has a plurality of lattice holes, and a mask chuck that is around (e.g., surrounds) the lattice support and supports an edge portion of the deposition mask. The deposition mask may be made of a non-magnetic material, and the lattice support may be made of a ferromagnetic material.

According to one or more embodiments of the present disclosure, the deposition apparatus may further include a magnetic force source that is above the substrate chuck and is configured or provided to apply a magnetic force to the lattice support.

According to one or more embodiments of the present disclosure, the magnetic force source may include a yoke plate, and a plurality of permanent magnets mounted on a bottom surface of the yoke plate.

According to one or more embodiments of the present disclosure, the deposition apparatus may further include a substrate chuck driver to move the substrate chuck in horizontal and vertical directions.

According to one or more embodiments of the present disclosure, the substrate chuck may be spaced and/or apart (e.g., spaced apart or separated) from the substrate chuck driver and connected to the substrate chuck driver by a plurality of connection members, and the magnetic force source may be disposed or provided between the substrate chuck and the substrate chuck driver.

According to one or more embodiments of the present disclosure, the substrate chuck driver may include a first platform connected to the substrate chuck, a second platform above the first platform, and six sub-actuators disposed or provided between the first platform and the second platform.

According to one or more embodiments of the present disclosure, the deposition apparatus may further include a second driver to move the magnetic force source to adjust a gap between the substrate chuck and the magnetic force source.

According to one or more embodiments of the present disclosure, the deposition apparatus may further include a substrate chuck driver to move the substrate chuck to adjust a position of the substrate chuck, and a second driver to move the magnetic force source to adjust a position of the magnetic force source.

The magnetic force source may be positioned or provided adjacent to a top surface of the substrate chuck by the second driver after the substrate is positioned or provided on the deposition mask by the substrate chuck driver.

According to one or more embodiments of the present disclosure, the deposition mask may include a mask frame having a plurality of cell openings and including a rib region that defines the plurality of cell openings, and a membrane having a plurality of pixel openings to communicate with the plurality of cell openings and disposed or provided on the mask frame.

According to one or more embodiments of the present disclosure, the lattice support may support the rib region, and the plurality of lattice holes may communicate with the plurality of cell openings.

According to one or more embodiments of the present disclosure, the lattice support may include a plurality of protrusions, and the rib region may be supported by the plurality of protrusions.

According to one or more embodiments of the present disclosure, the lattice support may include a lattice plate having the plurality of lattice holes, and a plurality of protrusions on the lattice plate. The deposition mask may be supported by the plurality of protrusions.

According to one or more embodiments of the present disclosure, the lattice support may be made of ferritic stainless steel, martensitic stainless steel, precipitation hardening stainless steel, and/or an invar alloy.

According to one or more embodiments of the present disclosure, the mask chuck may include an electrostatic electrode to provide an electrostatic force to hold the edge portion of the deposition mask.

One or more aspects of embodiments of the present disclosure are directed toward an electronic device. The electronic device may include a display panel. The display panel may include a substrate and light emitting layers formed or provided on the substrate by utilizing a deposition mask and a mask stage that supports the deposition mask. The mask stage may include a lattice support that supports the deposition mask and has a plurality of lattice holes, and a mask chuck that is around (e.g., surrounds) the lattice support and supports an edge portion of the deposition mask. The deposition mask may be made of a non-magnetic material, and the lattice support may be made of a ferromagnetic material.

According to one or more embodiments of the present disclosure, while the deposition process is being performed, the deposition mask may be supported by the lattice support and sufficiently or suitably brought into close contact with the backplane substrate by the magnetic force source. As a result, the pixel position accuracy (PPA) of deposition material layers on the backplane substrate may be improved or enhanced, and a color mixing phenomenon between sub-pixels may be reduced.

Additional aspects of embodiments will be set forth in part in the description which follows and, in part, will be apparent from the description or may be learned by practice of the presented embodiments of the disclosure.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings, in which:

FIG. 1 is a block diagram of an electronic device according to one or more embodiments of the present disclosure;

FIG. 2 is a schematic diagram of an electronic device according to one or more embodiments of the present disclosure;

FIG. 3 is an exploded perspective view illustrating a display device according to one or more embodiments of the present disclosure;

FIG. 4 is a block diagram illustrating the display device as illustrated in FIG. 3;

FIG. 5 is an equivalent circuit diagram illustrating an example of a first sub-pixel as illustrated in FIG. 4;

FIG. 6 is a schematic plan view illustrating an example of a display panel as illustrated in FIG. 3;

FIG. 7 is a schematic enlarged plan view illustrating an example of a display area as illustrated in FIG. 6;

FIG. 8 is a schematic enlarged plan view illustrating another example of the display area as illustrated in FIG. 6;

FIG. 9 is a schematic cross-sectional view illustrating an example of the display panel taken along the line I1-I1′ as illustrated in FIG. 7;

FIG. 10 is a schematic cross-sectional view illustrating another example of the display panel taken along the line I1-I1′ as illustrated in FIG. 7;

FIG. 11 is a schematic perspective view illustrating an example of a head mounted display;

FIG. 12 is a schematic exploded perspective view illustrating the head mounted display as illustrated in FIG. 11;

FIG. 13 is a schematic perspective view illustrating another example of the head mounted display;

FIG. 14 is a schematic diagram illustrating a mask stage and a deposition apparatus including the mask stage according to one or more embodiments of the present disclosure;

FIG. 15 is a schematic bottom view illustrating the backplane substrate as illustrated in FIG. 14;

FIG. 16 is a schematic plan view illustrating the deposition mask as illustrated in FIG. 14;

FIG. 17 is a schematic enlarged plan view illustrating the mask cell regions as illustrated in FIG. 16;

FIG. 18 is a schematic cross-sectional view taken along the line I2-I2′ as illustrated in FIG. 17;

FIG. 19 is a schematic plan view illustrating the mask stage as illustrated in FIG. 14;

FIGS. 20 and 21 are schematic cross-sectional views illustrating the mask stage as illustrated in FIG. 14;

FIG. 22 is a schematic enlarged cross-sectional view illustrating the magnetic force source and the lattice support as illustrated in FIG. 14;

FIGS. 23 and 24 are schematic side views illustrating the second driver as illustrated in FIG. 14; and

FIG. 25 is a schematic enlarged cross-sectional view illustrating another example of the lattice support as illustrated in FIG. 22.

### DETAILED DESCRIPTION

The subject matter of the present disclosure will be described more fully hereinafter with reference to the accompanying drawings, in which embodiments of the present disclosure are shown. The subject matter of the present disclosure may, however, be embodied in different forms and should not be construed as being limited to one or more embodiments set forth herein. Rather, these embodiments are provided as examples so that this disclosure will be thorough and complete and will fully convey the aspects and features of the present disclosure to those skilled in the art.

It will also be understood that if (e.g., when) an element or a layer is referred to as being “on” another element or layer, it may be directly on the other element or layer, or intervening elements or layers may also be present therebetween. In contrast, if (e.g., when) an element or a layer is referred to as being “directly on” another element or layer, there may be no intervening elements or layers present therebetween.

The same reference numbers indicate substantially the same components throughout the specification.

It will be understood that, although the terms “first,” “second,” and/or the like may be used herein to describe one or more suitable elements, these elements should not be limited by these terms. These terms are only used to distinguish one element from another element. For instance, a first element discussed in one or more embodiments may be termed a second element without departing from the spirit and scope of the present disclosure. Similarly, the second element may also be termed the first element.

The terminology used herein is for the purpose of describing particular embodiments only and is not intended to be limiting.

As used herein, “a”, “an,” “the,” and “at least one” do not denote a limitation of quantity and are intended to include both the singular and the plural, unless the context clearly indicates otherwise. For example, “an element” has substantially the same meaning as “at least one element,” unless the context clearly indicates otherwise. “At least one” is not to be construed as limiting “a” or “an. ” “Or” refers “and/or. ” As used herein, the term “and/or” includes any and all combinations of one or more of the associated listed items.

It will be further understood that the terms “has” and/or “having,” or “includes” and/or “including” if (e.g., when) used in this specification, specify the presence of stated features, regions, integers, steps, operations, elements, and/or components, but do not preclude the presence or addition of one or more other features, regions, integers, steps, operations, elements, components, and/or groups thereof. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Furthermore, relative terms, such as “lower” or “bottom” and “upper” or “top,” may be used herein to describe one element's relationship to another element as illustrated in the drawings. It will be understood that relative terms are intended to encompass different orientations of the device in addition to the orientation depicted in the drawings. For example, if (e.g., when) the device in one of the drawings is turned over, elements described as being on the “lower” side of other elements may then be oriented on “upper” sides of the other elements. The term “lower,” may therefore, encompasses both an orientation of “lower” and “upper,” depending on the particular orientation of the drawing. Similarly, if (e.g., when) the device in one of the drawings is turned over, elements described as “below” or “beneath” other elements may then be oriented “above” the other elements. The term “below” or “beneath” may, therefore, encompass both an orientation of above and below.

Features of each of one or more embodiments of the present disclosure may be partially or entirely combined with each other and may technically suitably interwork with each other, and respective embodiments may be implemented independently of each other or may be implemented together in association with each other.

“About” or “approximately” as used herein is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations or within ±30%, ±20%, ±10%, or ±5% of the stated value.

Unless otherwise defined, all terms (including technical and scientific terms) used herein have substantially the same meaning as generally understood by one of ordinary skill in the art to which the present disclosure belongs. It will be further understood that terms, such as those defined in generally used dictionaries, should be interpreted as having a meaning that is consistent with their meaning in the context of the relevant art and the present disclosure and will not be interpreted in an idealized or overly formal sense unless expressly so defined herein.

One or more embodiments of the present disclosure are described herein with reference to cross section illustrations that are schematic illustrations of idealized embodiments. As such, variations from the shapes of the illustrations as a result, for example, of manufacturing techniques and/or tolerances, are to be expected. Thus, one or more embodiments described herein should not be construed as being limited to the particular shapes of regions as illustrated herein but are to include deviations in shapes that result, for example, from manufacturing. For example, a region illustrated or described as flat (e.g., substantially flat) may have rough and/or nonlinear features. Moreover, sharp angles that are illustrated may be rounded. Thus, the regions as illustrated in the drawings are schematic in nature, and their shapes are not intended to illustrate the precise shape of a region and are not intended to limit the scope of the appended claims and equivalents thereof.

Hereinafter, one or more embodiments will be described in more detail with reference to the accompanying drawings.

The display device according to one or more embodiments of the present disclosure may be applied to one or more suitable electronic devices. The electronic device according to one or more embodiments of the present disclosure may include the display device as described in one or more embodiments and may further include modules or devices having additional functions in addition to the display device.

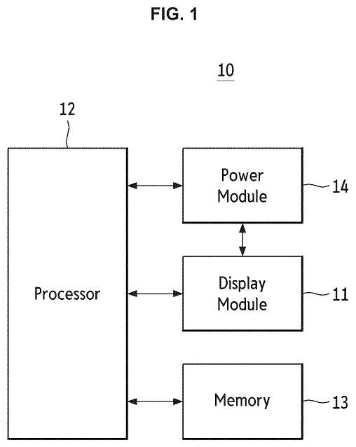

FIG. 1 is a block diagram of an electronic device according to one or more embodiments of the present disclosure.

Referring to FIG. 1, the electronic device 10 according to one or more embodiments of the present disclosure may include a display module 11, a processor 12, a memory 13, and a power module 14.

The processor 12 may include at least one selected from among a central processing unit (CPU), an application processor (AP), a graphic processing unit (GPU), a communication processor (CP), an image signal processor (ISP), and a controller.

The memory 13 may store data information desired or necessary for the operation of the processor 12 or the display module 11. If (e.g., when) the processor 12 executes an application stored in the memory 13, an image data signal and/or an input control signal may be transmitted to the display module 11, and the display module 11 may process the received signal and output image information through a display screen.

The power module 14 may include a power supply module, such as, for example, a power adapter and/or a battery, and a power conversion module that converts the power supplied by the power supply module to generate power desired or necessary for the operation of the electronic device 10.

At least one selected from among the components of the electronic device 10 according to one or more embodiments of the present disclosure may be included in the display device 20 according to one or more embodiments of the present disclosure. In one or more embodiments, one or more suitable modules of the individual modules functionally included in one module may be included in the display device 20, and other modules may be provided separately from the display device 10. For example, the display device 20 may include the display module 11, and the processor 12, the memory 13, and the power module 14 may be provided in the form of other devices within the electronic device 10 other than the display device 20.

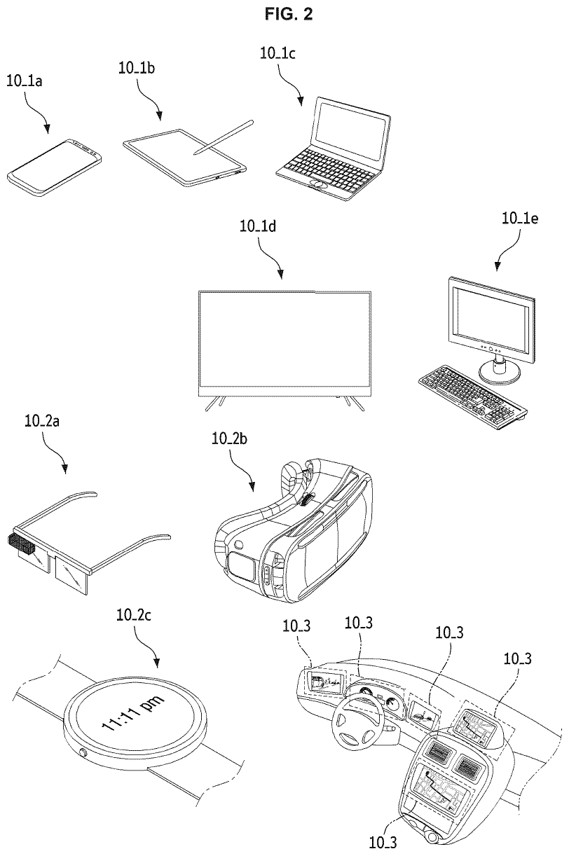

FIG. 2 is a schematic diagram of an electronic device according to one or more embodiments of the present disclosure.

Referring to FIG. 2, one or more suitable electronic devices to which display devices 20 according to one or more embodiments of the present disclosure are applied may include not only image display electronic devices, such as a smart phone 10_1a, a tablet PC (personal computer) 10_1b, a laptop 10_1c, a TV 10_1d, and/or a desk monitor 10_1e, but also wearable electronic devices including display modules, such as, for example, smart glasses 10_2a, a head mounted display 10_2b, and/or a smart watch 10_2c, and vehicle electronic devices 10_3 including display modules, such as a Center Information Display (CID) and/or a room mirror display arranged on a dashboard, center fascia, and/or dashboard of an automobile.

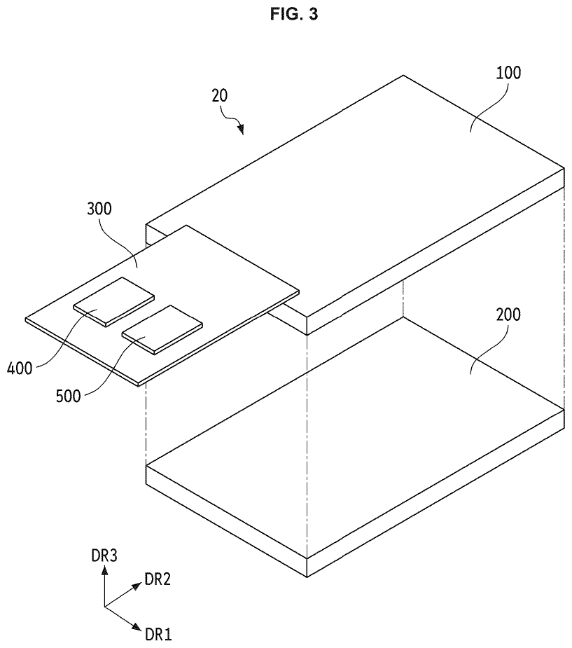

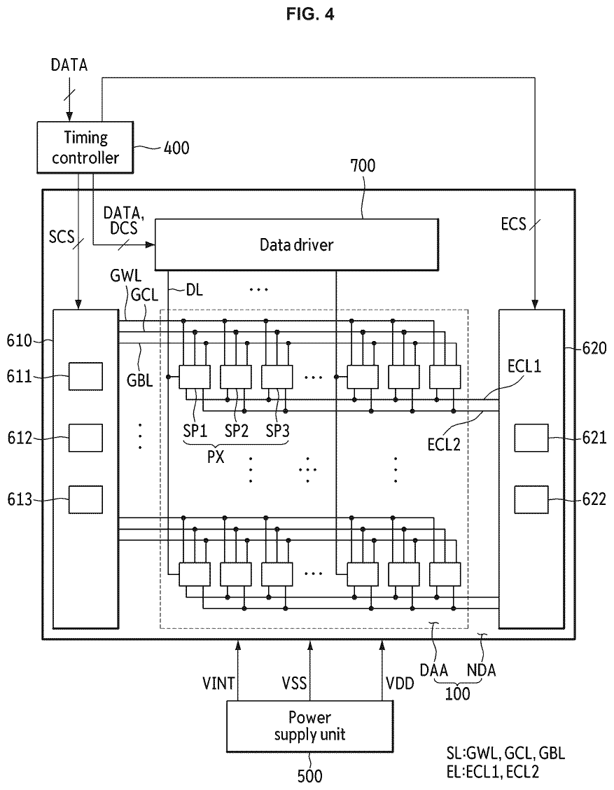

FIG. 3 is an exploded perspective view illustrating a display device according to one or more embodiments of the present disclosure. FIG. 4 is a block diagram illustrating the display device as illustrated in FIG. 3.

Referring to FIGS. 3 and 4, a display device 20 according to one or more embodiments may be a device that displays a moving image and/or a still image. A display device 20 according to one or more embodiments may be used as the electronic device 10 or the display module 11 of the electronic device 10. For example, the display device 20 according to one or more embodiments may be applied to portable electronic devices 10, such as a mobile phone, a smartphone, a tablet personal computer, a mobile communication terminal, an electronic organizer, an electronic book, a portable multimedia player (PMP), a navigation system, an ultra mobile PC (UMPC), and/or the like. The display device 20 according to one or more embodiments may be applied as a display module 11 of electronic devices 10, such as a television, a laptop, a monitor, a billboard, an Internet-of-Things (IoT) terminal (or an IoT device, and/or the like. The display device 20 according to one or more embodiments may be applied to electronic devices 10, such as a smart watch, a watch phone, a head mounted display (HMD) to implement virtual reality and/or augmented reality, and/or the like.

The display device 20 according to one or more embodiments may include a display panel 100, a heat dissipation layer 200, a circuit board 300, a timing control circuit 400, and a power supply circuit 500.

The display panel 100 may have a planar shape (e.g., a substantially planar shape) similar to a quadrilateral shape (e.g., a substantially quadrilateral shape). For example, the display panel 100 may have a planar shape (e.g., a substantially planar shape) similar to a quadrilateral shape (e.g., a substantially quadrilateral shape), having a short side of a first direction DR1 and a long side of a second direction DR2 that crosses (e.g., intersects) the first direction DR1. In the display panel 100, a corner where a short side in the first direction DR1 and a long side in the second direction DR2 meet may be right-angled or rounded with a set or predetermined curvature. The planar shape (e.g., the substantially planar shape) of the display panel 100 is not limited to a quadrilateral shape (e.g., a substantially quadrilateral shape), and may be a shape similar to another polygonal shape (e.g., substantially polygonal shape), a circular shape (e.g., a substantially circular shape), or an elliptical shape (e.g., a substantially elliptical shape). The planar shape (e.g., the substantially planar shape) of the display device 20 may conform to the planar shape (e.g., the substantially planar shape) of the display panel 100, but embodiments of the present disclosure are not limited thereto.

The display panel 100 may include a plurality of pixels PX, a plurality of scan lines SL, a plurality of emission control lines EL, a plurality of data lines DL, a scan driver 610, an emission driver 620, and a data driver 700. The display panel 100 may be divided into a display area DAA that displays an image and a non-display area NDA that does not display an image as illustrated in FIG. 4.

The plurality of pixels PX may be disposed or provided in the display area DAA. The plurality of pixels PX may be arranged or provided in a matrix form along the first direction DR1 and the second direction DR2. The plurality of scan lines SL and the plurality of emission control lines EL may extend in the first direction DR1, while being arranged or provided in the second direction DR2. The plurality of data lines DL may extend in the second direction DR2, while being arranged or provided in the first direction DR1.

The plurality of scan lines SL may include a plurality of write scan lines GWL, a plurality of control scan lines GCL, and a plurality of bias scan lines GBL. The plurality of emission control lines EL may include a plurality of first emission control lines ECL1 and a plurality of second emission control lines ECL2.

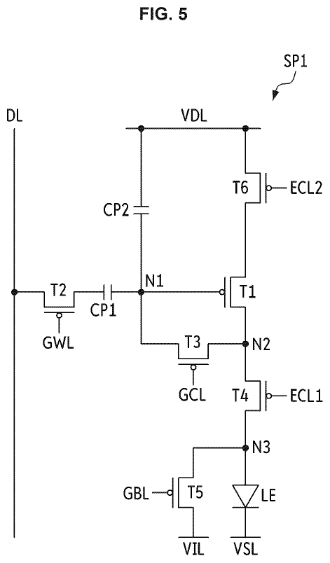

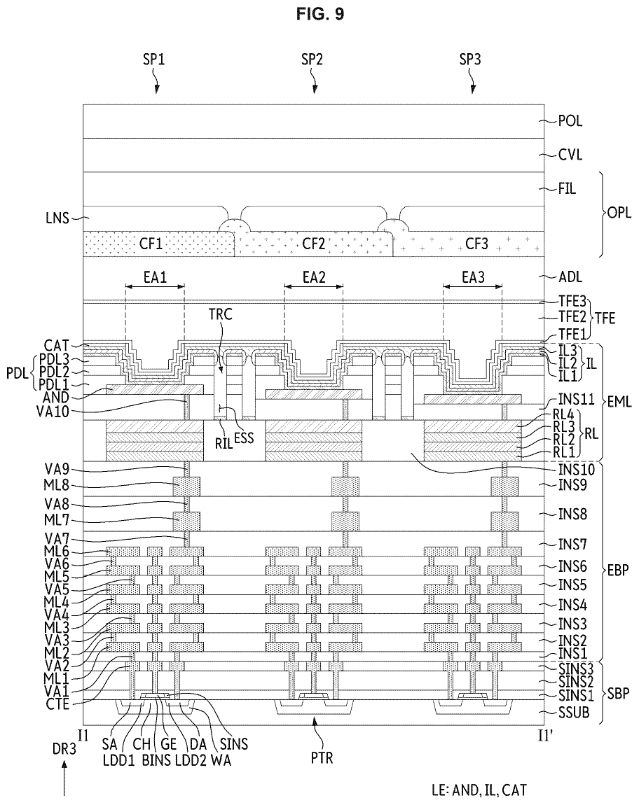

The plurality of pixels PX may include a plurality of sub-pixels SP1, SP2, and SP3. The plurality of sub-pixels SP1, SP2, and SP3 may include a plurality of pixel transistors as illustrated in FIG. 5, and the plurality of pixel transistors may be formed or provided by a semiconductor process and disposed or provided on a semiconductor substrate SSUB (see FIG. 9). For example, the plurality of pixel transistors of the data driver 700 may be of complementary metal oxide semiconductor (CMOS), but embodiments of the present disclosure are not limited thereto.

Each of the plurality of sub-pixels SP1, SP2, and SP3 may be connected to one write scan line GWL, one control scan line GCL, one bias scan line GBL, one first emission control line ECL1, one second emission control line ECL2, and one data line DL. Each of the plurality of sub-pixels SP1, SP2, and SP3 may receive a data voltage of the data line DL in response to a write scan signal of the write scan line GWL, and emit light from the light emitting element according to the data voltage.

The scan driver 610, the emission driver 620, and the data driver 700 may be disposed or provided in the non-display area NDA.

The scan driver 610 may include a plurality of scan transistors, and the emission driver 620 may include a plurality of light emitting transistors. The plurality of scan transistors and the plurality of light emitting transistors may be formed or provided on the semiconductor substrate SSUB (see FIG. 9) through a semiconductor process. For example, the plurality of scan transistors and the plurality of light emitting transistors may be of CMOS, but embodiments of the present disclosure are not limited thereto.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and output them sequentially to the write scan lines GWL. The control scan signal output unit 612 may generate control scan signals in response to the scan timing control signal SCS and sequentially output them to the control scan lines GCL. The bias scan signal output unit 613 may generate bias scan signals according to the scan timing control signal SCS and output them sequentially to the bias scan lines GBL.

The emission driver 620 may include a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and sequentially output them to the first emission control lines ECL1. The second emission control driver 622 may generate second emission control signals according to the emission timing control signal ECS and sequentially output them to the second emission control lines ECL2.

The data driver 700 may include a plurality of data transistors, and the plurality of data transistors may be formed or provided on the semiconductor substrate SSUB (see FIG. 9) through a semiconductor process. For example, the plurality of data transistors may be of CMOS, but embodiments of the present disclosure are not limited thereto.

The data driver 700 may receive digital video data DATA and a data timing control signal DCS from the timing control circuit 400. The data driver 700 may convert the digital video data DATA into analog data voltages according to the data timing control signal DCS and output the analog data voltages to the data lines DL. In one or more embodiments, the sub-pixels SP1, SP2, and SP3 may be selected by the write scan signal of the scan driver 610, and data voltages may be supplied to the selected sub-pixels SP1, SP2, and SP3.

The heat dissipation layer 200 may overlap the display panel 100 in a third direction DR3, which is a thickness direction of the display panel 100. The heat dissipation layer 200 may be disposed or provided on one surface of the display panel 100, for example, on the rear surface thereof. The heat dissipation layer 200 may serve to dissipate heat generated from the display panel 100. The heat dissipation layer 200 may include a metal layer having high thermal conductivity, such as graphite, silver (Ag), copper (Cu), and/or aluminum (Al).

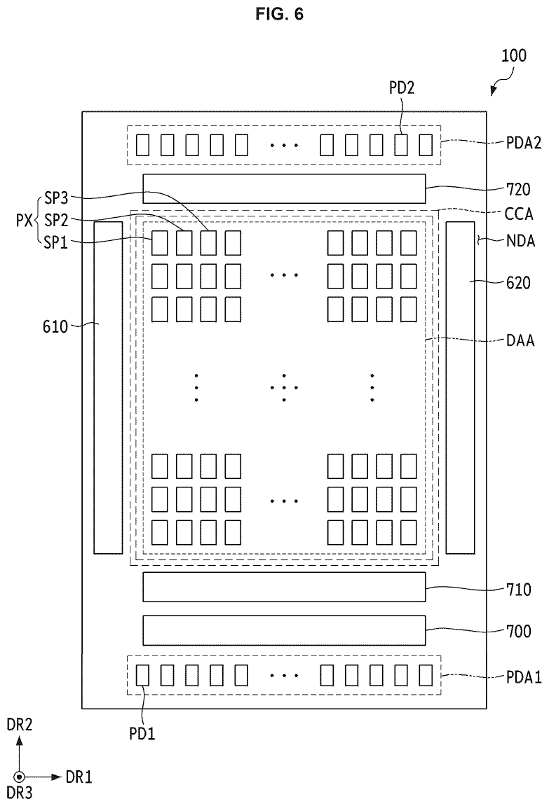

The circuit board 300 may be electrically connected to a plurality of first pads PD1 (see FIG. 6) of a first pad portion PDA1 (see FIG. 6) of the display panel 100 by utilizing a conductive (e.g., electrically conductive) adhesive member, such as an anisotropic conductive film. The circuit board 300 may be a flexible printed circuit board having a flexible material, or a flexible film. Although the circuit board 300 is illustrated in FIG. 3 as being unfolded, the circuit board 300 may be bent. In one or more embodiments, one end of the circuit board 300 may be disposed or provided on the rear surface of the display panel 100 and/or the rear surface of the heat dissipation layer 200. The other end of the circuit board 300 may be connected to the plurality of first pads PD1 (see FIG. 6) of the first pad portion PDA1 (see FIG. 6) of the display panel 100 by utilizing a conductive (e.g., electrically conductive) adhesive member. One end of the circuit board 300 may be an opposite end of the other end of the circuit board 300.

The timing control circuit 400 may receive digital video data and timing signals inputted from the outside. The timing control circuit 400 may generate the scan timing control signal SCS, the emission timing control signal ECS, and the data timing control signal DCS to control the display panel 100 in response to the timing signals. The timing control circuit 400 may output the scan timing control signal SCS to the scan driver 610 and output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and supply them to the display panel 100. The first driving voltage VSS, the second driving voltage VDD, and the third driving voltage VINT will be described herein in more detail in conjunction with FIG. 5.

Each of the timing control circuit 400 and the power supply circuit 500 may be formed or provided as an integrated circuit (IC) and attached to one surface of the circuit board 300. In one or more embodiments, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In one or more embodiments, each of the timing control circuit 400 and the power supply circuit 500 may be disposed or provided in the non-display area NDA of the display panel 100, similarly to the scan driver 610, the emission driver 620, and the data driver 700. In one or more embodiments, the timing control circuit 400 may include a plurality of timing transistors, and each power supply circuit 500 may include a plurality of power transistors. The plurality of timing transistors and the plurality of power transistors may be formed or provided on the semiconductor substrate SSUB (see FIG. 9) through a semiconductor process. For example, the plurality of timing transistors and the plurality of power transistors may be of CMOS, but embodiments of the present disclosure are not limited thereto. Each of the timing control circuit 400 and the power supply circuit 500 may be disposed or provided between the data driver 700 and the first pad portion PDA1 (see FIG. 6).

FIG. 5 is an equivalent circuit diagram illustrating an example of a first sub-pixel as illustrated in FIG. 4.

Referring to FIG. 5, the first sub-pixel SP1 may be connected to the write scan line GWL, the control scan line GCL, the bias scan line GBL, the first emission control line ECL1, the second emission control line ECL2, and the data line DL. Further, the first sub-pixel SP1 may be connected to a first driving voltage line VSL to which the first driving voltage VSS that corresponds to a low potential voltage is applied, a second driving voltage line VDL to which the second driving voltage VDD that corresponds to a high potential voltage is applied, and a third driving voltage line VIL to which the third driving voltage VINT that corresponds to an initialization voltage is applied.

The first sub-pixel SP1 may include a plurality of transistors T1 to T6, a light emitting element LE, a first capacitor CP1, and a second capacitor CP2.

The light emitting element LE may emit light in response to a driving current that flows through the channel of the first transistor T1. The emission amount of the light emitting element LE may be proportional to the driving current. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed or provided between the first electrode and the second electrode, but embodiments of the present disclosure are not limited thereto. For example, the light emitting element LE may be an inorganic light emitting element including a first electrode, a second electrode, and an inorganic semiconductor disposed or provided between the first electrode and the second electrode, in which case the light emitting element LE may be a micro light emitting diode.

The first transistor T1 may be a driving transistor that controls a source-drain current (hereinafter referred to as “driving current”) that flows between the source electrode and the drain electrode thereof according to a voltage applied to the gate electrode thereof.

A second transistor T2 may be disposed or provided between one electrode of the first capacitor CP1 and the data line DL. The second transistor T2 may be turned on by the write scan signal of the write scan line GWL to connect the one electrode of the first capacitor CP1 to the data line DL. Accordingly, the data voltage of the data line DL may be applied to the one electrode of the first capacitor CP1.

A third transistor T3 may be disposed or provided between the first node N1 and the second node N2. The third transistor T3 may be turned on by the control scan signal of the control scan line GCL to connect the first node N1 to the second node N2. For this reason, If (e.g., when) the gate electrode and the source electrode of the first transistor T1 are connected, the first transistor T1 may operate substantially the same as a diode.

The fourth transistor T4 may be connected between the second node N2 and a third node N3. The fourth transistor T4 may be turned on by the first emission control signal of the first emission control line ECL1 to connect the second node N2 to the third node N3. Accordingly, the driving current of the first transistor T1 may be supplied to the light emitting element LE. A fifth transistor T5 may be disposed or provided between the third node N3 and the third driving voltage line VIL. The fifth transistor T5 may be turned on by the bias scan signal of the bias scan line GBL to connect the third node N3 to the third driving voltage line VIL. Accordingly, the third driving voltage VINT of the third driving voltage line VIL may be applied to the first electrode of the light emitting element LE.

The sixth transistor T6 may be disposed or provided between the source electrode of the first transistor T1 and the second driving voltage line VDL. The sixth transistor T6 may be turned on by the second emission control signal of the second emission control line ECL2 to connect the source electrode of the first transistor T1 to the second driving voltage line VDL. Accordingly, the second driving voltage VDD of the second driving voltage line VDL may be applied to the source electrode of the first transistor T1.

The first capacitor CP1 may be formed or provided between the first node N1 and the drain electrode of the second transistor T2. The second capacitor CP2 may be formed or provided between the gate electrode of the first transistor T1 and the second driving voltage line VDL.

Each of the first transistor T1 to the sixth transistor T6 may be a metal-oxide-semiconductor field effect transistor (MOSFET). For example, each of the first transistor T1 to the sixth transistor T6 may be a positive type or kind (or P-type or kind) MOSFET, but embodiments of the present disclosure are not limited thereto.

Each of the first transistor T1 to the sixth transistor T6 may be a negative type or kind (or N-type or kind) MOSFET. In one or more embodiments, one or more of the first transistor T1 to the sixth transistor T6 may be P-type or kind MOSFETs, and each of the remaining transistors may be an N-type or kind MOSFET.

Although it is illustrated in FIG. 5 that the first sub-pixel SP1 includes six transistors T1 to T6 and two capacitors C1 and C2, it should be noted that the equivalent circuit diagram of the first sub-pixel SP1 is not limited to that as illustrated in FIG. 5. For example, the number of transistors and the number of capacitors of the first sub-pixel SP1 are not limited to those as illustrated in FIG. 5.

Further, the equivalent circuit diagram of the second sub-pixel SP2 and the equivalent circuit diagram of the third sub-pixel SP3 may be substantially the same as the equivalent circuit diagram of the first sub-pixel SP1 as described in conjunction with FIG. 5. Therefore, the description of the equivalent circuit diagram of the second sub-pixel SP2 and the equivalent circuit diagram of the third sub-pixel SP3 may not be repeated in the present disclosure.

FIG. 6 is a schematic plan view illustrating an example of a display panel as illustrated in FIG. 3.

Referring to FIG. 6, the display area DAA of the display panel 100 according to one or more embodiments may include the plurality of pixels PX arranged or provided in a matrix form. The non-display area NDA of the display panel 100 according to one or more embodiments may include the scan driver 610, the emission driver 620, the data driver 700, a first distribution circuit 710, a second distribution circuit 720, the first pad portion PDA1, and a second pad portion PDA2.

The scan driver 610 may be disposed or provided on the first side of the display area DAA, and the emission driver 620 may be disposed or provided on the second side of the display area DAA. For example, the scan driver 610 may be disposed or provided on one side of the display area DAA in the first direction DR1, and the emission driver 620 may be disposed or provided on the other side of the display area DAA in the first direction DR1. However, embodiments of the present disclosure are not limited thereto, and the scan driver 610 and the emission driver 620 may be disposed or provided on both (e.g., simultaneously) the first side and the second side of the display area DAA.

The first pad portion PDA1 may include the plurality of first pads PD1 connected to pads or bumps of the circuit board 300 through a conductive (e.g., electrically conductive) adhesive member. The first pad portion PDA1 may be disposed or provided on the third side of the display area DAA. For example, the first pad portion PDA1 may be disposed or provided on one side of the display area DAA in the second direction DR2. The first pad portion PDA1 may be disposed or provided outside the data driver 700 in the second direction DR2.

The second pad portion PDA2 may include a plurality of second pads PD2 that correspond to inspection pads that test whether the display panel 100 operates normally or suitably. The plurality of second pads PD2 may be connected to a jig or a probe pin during an inspection process or may be connected to a circuit board for inspection. The circuit board for inspection may be a printed circuit board made of a rigid material or a flexible printed circuit board made of a flexible material.

The second pad portion PDA2 may be disposed or provided on the fourth side of the display area DAA. For example, the second pad portion PDA2 may be disposed or provided on the other side of the display area DAA in the second direction DR2. The second pad portion PDA2 may be disposed or provided outside the second distribution circuit 720 in the second direction DR2.

The first distribution circuit 710 may distribute data voltages applied through the first pad portion PDA1 to the plurality of data lines DL. For example, the first distribution circuit 710 may distribute the data voltages applied through one first pad PD1 of the first pad portion PDA1 to the P (P may be a positive integer of 2 or more) data lines DL, and, as a result, the number of the plurality of first pads PD1 may be reduced. The first distribution circuit 710 may be disposed or provided on the third side of the display area DAA of the display panel 100. For example, the first distribution circuit 710 may be disposed or provided on one side of the display area DAA in the second direction DR2.

The second distribution circuit 720 may distribute signals applied through the second pad portion PDA2 to the scan driver 610, the emission driver 620, and the data lines DL. The second pad portion PDA2 and the second distribution circuit 720 may be configured or provided to inspect the operation of each of the pixels PX in the display area DAA. The second distribution circuit 720 may be disposed or provided on the fourth side of the display area DAA of the display panel 100. For example, the second distribution circuit 720 may be disposed or provided on the other side of the display area DAA in the second direction DR2.

A cathode connection part CCA may be a region where a second electrode CAT (see FIG. 9) of a display element layer EML (see FIG. 9) is connected to the first driving voltage line VSL of the non-display area NDA. The cathode connection part CCA may be disposed or provided outside at least one side of the display area DAA. For example, the cathode connection part CCA may be disposed or provided outside at least on one side among the left side, the right side, the upper side, and the lower side of the display area DAA. In one or more embodiments, the cathode connection part CCA may be disposed or provided to be around (e.g., surround) the display area DAA as illustrated in FIG. 6 in order to minimize or reduce a deviation in the first driving voltage VSS caused by voltage drop (IR drop) or voltage rise (IR rising) of the second electrode CAT in the display area DAA.

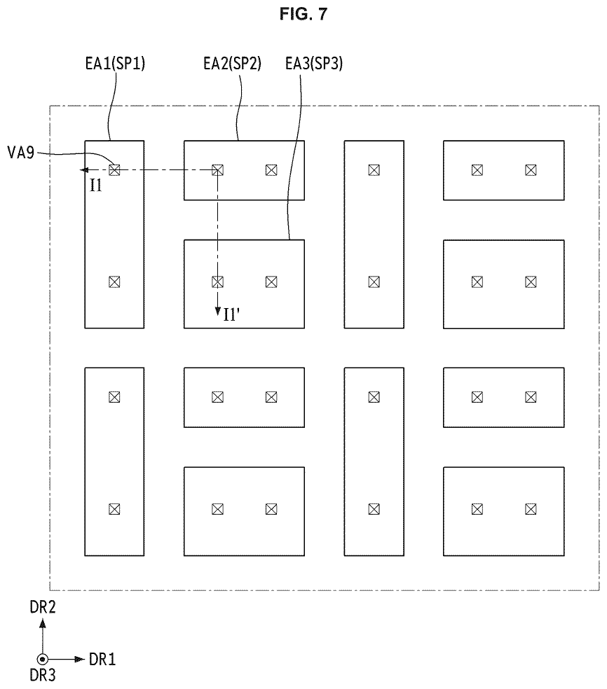

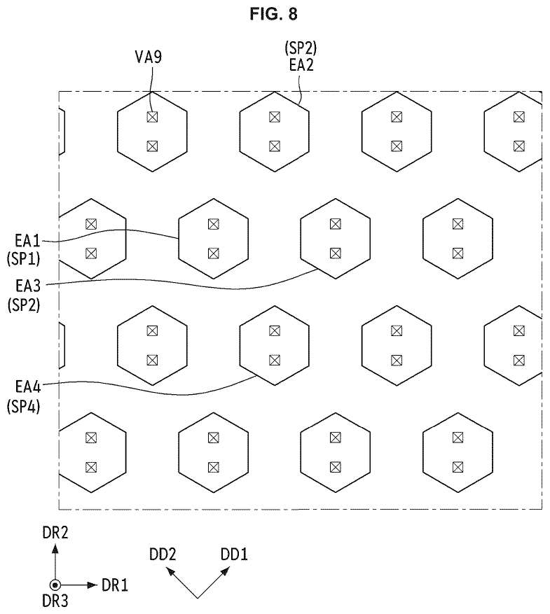

FIG. 7 is a schematic enlarged plan view illustrating an example of a display area as illustrated in FIG. 6. FIG. 8 is a schematic enlarged plan view illustrating another example of the display area as illustrated in FIG. 6.

Referring to FIGS. 7 and 8, each of the pixels PX may include the first emission area EA1 that is an emission area of the first sub-pixel SP1, the second emission area EA2 that is an emission area of the second sub-pixel SP2, and the third emission area EA3 that is an emission area of the third sub-pixel SP3.

The first emission area EA1, the second emission area EA2, and the third emission area EA3 may have, in a plan view, a quadrilateral shape (e.g., a substantially quadrilateral shape) or a hexagonal shape (e.g., a substantially hexagonal shape) as illustrated in FIGS. 7 and 8, but embodiments of the present disclosure are not limited thereto. The first emission area EA1, the second emission area EA2, and the third emission area EA3 may have a polygonal shape (e.g., a substantially polygonal shape) other than a quadrangle shape (e.g., a substantially quadrangle shape), a hexagonal shape (e.g., a substantially hexagonal shape), a circular shape (e.g., a substantially circular shape), an elliptical shape (e.g., a substantially elliptical shape), or an atypical shape in a plan view.

As illustrated in FIG. 7, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In one or more embodiments, the second emission area EA2 and the third emission area EA3 may be adjacent to each other in the second direction DR2. The area of the first emission area EA1, the area of the second emission area EA2, and the area of the third emission area EA3 may be different.

In one or more embodiments, as illustrated in FIG. 8, the emission areas EA1, EA2, EA3, and EA4 may have a hexagonal shape (e.g., a substantially hexagonal shape) in a plan view. In one or more embodiments, the first emission area EA1 and the third emission area EA3 may be adjacent in the first direction DR1, and the second emission area EA2 and the fourth emission area EA4 may be adjacent in the second direction DR2. In one or more embodiments, the first emission area EA1 and the second emission area EA2 may be adjacent in a first diagonal direction DD1, and the second emission area EA2 and the third emission area EA3 may be adjacent in a second diagonal direction DD2. In one or more embodiments, the first emission area EA1 and the fourth emission area EA4 may be adjacent in the second diagonal direction DD2, and the third emission area EA3 and the fourth emission area EA4 may be adjacent in the first diagonal direction DD1. The first diagonal direction DD1 may be a direction between the first direction DR1 and the second direction DR2 and may refer to a direction inclined by 45 degrees with respect to the first direction DR1 and the second direction DR2, and the second diagonal direction DD2 may be a direction perpendicular (e.g., substantially perpendicular) to the first diagonal direction DD1.

The first sub-pixel SP1 may emit first light, the second sub-pixel SP2 may emit second light, and the third sub-pixel SP3 may emit third light. Herein, the first light may be light of a blue wavelength band, the second light may be light of a green wavelength band, and the third light may be light of a red wavelength band. For example, the blue wavelength band may be a wavelength band of light whose main or predominant peak wavelength is in the range of about 370 nm to 460 nm, the green wavelength band may be a wavelength band of light whose main or predominant peak wavelength is in the range of about 480 nm to 560 nm, and the red wavelength band may be a wavelength band of light whose main or predominant peak wavelength is in the range of about 600 nm to 750 nm.

As illustrated in FIG. 7, each of the plurality of pixels PX may include three emission areas EA1, EA2, and EA3 or may include four emission areas EA1, EA2, EA3, and EA4 as illustrated in FIG. 8. In one or more embodiments, the fourth emission area EA4 may emit substantially the same second light as the second emission area EA2, but embodiments of the present disclosure are not limited thereto.

The emission areas of the plurality of pixels PX may be arranged or provided in a stripe structure (e.g., a substantially stripe structure) in which the emission areas are arranged or provided in the first direction DR1, a PENTILE® structure in which the emission areas EA1, EA2, EA3, and EA4 are arranged or provided in a rhombic shape (e.g., a substantially rhombic shape) as illustrated in FIG. 8, or a hexagonal structure (e.g., a substantially hexagonal structure) in which the emission areas are arranged or provided in a hexagonal shape (e.g., a substantially hexagonal shape). PENTILE® is a duly registered trademark of Samsung Display Co., Ltd.

FIG. 9 is a schematic cross-sectional view illustrating an example of the display panel taken along the line I1-I1′ as illustrated in FIG. 7.

Referring to FIG. 9, the display panel 100 may include a semiconductor backplane SBP, a light emitting element backplane EBP, the display element layer EML, an encapsulation layer TFE, an optical layer OPL, a cover layer CVL, and a polarizing plate POL.

The semiconductor backplane SBP may include the semiconductor substrate SSUB including a plurality of pixel transistors PTR, a plurality of semiconductor insulating (e.g., electrically insulating) films that cover the plurality of pixel transistors PTR, and a plurality of contact terminals CTE electrically connected to the plurality of pixel transistors PTR, respectively. The plurality of pixel transistors PTR may be the first transistor T1 to the sixth transistor T6 as described with reference to FIG. 5.

The semiconductor substrate SSUB may be a silicon substrate, a germanium substrate, and/or a silicon-germanium substrate. The semiconductor substrate SSUB may be a substrate doped with a first type or kind impurity. A plurality of well regions WA may be disposed or provided on the top surface of the semiconductor substrate SSUB. The plurality of well regions WA may be regions doped with a second type or kind impurity. The second type or kind impurity may be different from the first type or kind impurity. For example, if (e.g., when) the first type or kind impurity is a p-type or kind impurity, the second type or kind impurity may be an n-type or kind impurity. In one or more embodiments, if (e.g., when) the first type or kind impurity is an n-type or kind impurity, the second type or kind impurity may be a p-type or kind impurity.

Each of the plurality of well regions WA may include a source region SA that corresponds to the source electrode of the pixel transistor PTR, a drain region DA that corresponds to the drain electrode thereof, and a channel region CH disposed or provided between the source region SA and the drain region DA.

A lower insulating film BINS may be disposed or provided between a gate electrode GE and the well region WA. A side insulating film SINS may be disposed or provided on the side surface of the gate electrode GE. The side insulating film SINS may be disposed or provided on the lower insulating film BINS.

Each of the source region SA and the drain region DA may be a region doped with the first type or kind impurity. The gate electrode GE of the pixel transistor PTR may overlap the well region WA in the third direction DR3, which is the thickness direction of the semiconductor substrate SSUB. The channel region CH may overlap the gate electrode GE in the third direction DR3. The source region SA may be disposed or provided on one side of the gate electrode GE, and the drain region DA may be disposed or provided on the other side of the gate electrode GE.

Each of the plurality of well regions WA may further include a first low-concentration impurity region LDD1 disposed or provided between the channel region CH and the source region SA and a second low-concentration impurity region LDD2 disposed or provided between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the first low-concentration impurity region LDD1 and the second low-concentration impurity region LDD2, thereby increasing the length of the channel region CH of each of the pixel transistors PTR.

A first semiconductor insulating film SINS1 may be disposed or provided on the semiconductor substrate SSUB. A second semiconductor insulating film SINS2 may be disposed or provided on the first semiconductor insulating film SINS1.

The plurality of contact terminals CTE may be disposed or provided on the second semiconductor insulating film SINS2. Each of the plurality of contact terminals CTE may be connected to any one selected from among the gate electrode GE, the source region SA, and the drain region DA of each of the pixel transistors PTR through a hole that penetrates the first semiconductor insulating film SINS1 and the second semiconductor insulating film SINS2. The plurality of contact terminals CTE may be of any one of copper (Cu), aluminum (Al), tungsten (W), molybdenum (Mo), chromium (Cr), gold (Au), titanium (Ti), nickel (Ni), and neodymium (Nd), or an alloy including any one selected from among them.

A third semiconductor insulating film SINS3 may be disposed or provided on a side surface of each of the plurality of contact terminals CTE. The top surface of each of the plurality of contact terminals CTE may be exposed without being covered by the third semiconductor insulating film SINS3.

Each of the first semiconductor insulating film SINS1, the second semiconductor insulating film SINS2, and the third semiconductor insulating film SINS3 may be of silicon carbonitride (e.g., SiCN) or a silicon oxide (e.g., SiOₓ, wherein 0<X≤2; e.g., SiO₂)-based inorganic film, but embodiments of the present disclosure are not limited thereto.

The semiconductor substrate SSUB may be replaced with a glass substrate and/or a polymer resin substrate, such as polyimide. In one or more embodiments, thin film transistors may be disposed or provided on the glass substrate and/or the polymer resin substrate. The glass substrate may be a rigid substrate that does not bend, and the polymer resin substrate may be a flexible substrate that may be bent and/or curved.

The light emitting element backplane EBP may include a plurality of conductive layers ML1 to ML8, a plurality of vias VA1 to VA9, and a plurality of interlayer insulating films INS1 to INS9.

The first interlayer insulating film INS1 to the ninth interlayer insulating film INS9 may serve to insulate (e.g., electrically insulate) the first conductive layer ML1 to the eighth conductive layer ML8. The first conductive layer ML1 to the eighth conductive layer ML8 may serve to connect the plurality of contact terminals CTE exposed from the semiconductor backplane SBP to thereby implement the circuit of the first sub-pixel SP1 as illustrated in FIG. 5.

For example, the first transistor T1 to the sixth transistor T6 may be formed or provided in the semiconductor backplane SBP, and the connection of the first transistor T1 to the sixth transistor T6 and the first capacitor C1 and the second capacitor C2 may be accomplished through the first conductive layer ML1 to the eighth conductive layer ML8. In one or more embodiments, the connection between the drain region that corresponds to the drain electrode of the fourth transistor T4, the source region that corresponds to the source electrode of the fifth transistor T5, and a first electrode AND of the light emitting element LE may also be accomplished through the first conductive layer ML1 to the eighth conductive layer ML8.

The first conductive layer ML1 to the eighth conductive layer ML8 and the first via VA1 to the eighth via VA8 may be of substantially the same material. The first conductive layer ML1 to the eighth conductive layer ML8 and the first via VA1 to the eighth via VA8 may be of any one of copper (Cu), aluminum (Al), tungsten (W), molybdenum (Mo), chromium (Cr), gold (Au), titanium (Ti), nickel (Ni), and neodymium (Nd), or an alloy including any one selected from among them. The first via VA1 to the eighth via VA8 may be made of substantially the same material. The first interlayer insulating film INS1 to the eighth interlayer insulating film INS8 may be of a silicon oxide (e.g., SiOₓ, wherein 0<X≤2; e.g., SiO₂)-based inorganic layer, but embodiments of the present disclosure are not limited thereto.

A ninth interlayer insulating film INS9 may be disposed or provided on the eighth interlayer insulating film INS8 and the eighth conductive layer ML8. The ninth interlayer insulating film INS9 may be of a silicon oxide (e.g., SiOₓ, wherein 0<X≤2; e.g., SiO₂)-based inorganic film, but embodiments of the present disclosure are not limited thereto.

Each of the ninth vias VA9 may penetrate the ninth interlayer insulating film INS9 and be connected to the exposed eighth conductive layer ML8. The ninth vias VA9 may be of any one of copper (Cu), aluminum (Al), tungsten (W), molybdenum (Mo), chromium (Cr), gold (Au), titanium (Ti), nickel (Ni), and neodymium (Nd), or an alloy including any one selected from among them.

The display element layer EML may be disposed or provided on the light emitting element backplane EBP. The display element layer EML may include the tenth interlayer insulating film INS10 and the eleventh interlayer insulating film INS11, reflective electrodes RL, the first electrodes AND, a light emitting stack IL, the second electrode CAT, a pixel defining film PDL, and a plurality of trenches TRC.

The reflective electrodes RL may be disposed or provided on the ninth interlayer insulating film INS9. Each of the reflective electrodes RL may include at least one reflective electrode RL1, RL2, RL3, and RL4. For example, each of the reflective electrodes RL may include the first reflective electrode RL1, the second reflective electrode RL2, the third reflective electrode RL3, and the fourth reflective electrode RL4 as illustrated in FIG. 9.

The first reflective electrodes RL1 may be disposed or provided on the ninth interlayer insulating film INS9 and may be connected to the ninth via VA9. Each of the second reflective electrodes RL2 may be disposed or provided on the first reflective electrode RL1 that corresponds thereto. Each of the third reflective electrodes RL3 may be disposed or provided on the second reflective electrode RL2 that corresponds thereto. Each of the fourth reflective electrodes RL4 may be disposed or provided on the third reflective electrode RL3 that corresponds thereto.

Because the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4.

The first reflective electrodes RL1 may be of any one of copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the first reflective electrodes RL1 may contain titanium nitride (e.g., TiNₓ, wherein 0<X≤2; e.g., TiN), the second reflective electrodes RL2 may contain aluminum (Al), the third reflective electrodes RL3 may contain titanium nitride (e.g., TiNₓ, wherein 0<X≤2; e.g., TiN), and the fourth reflective electrodes RL4 may include titanium (Ti).

The tenth interlayer insulating film INS10 may be disposed or provided on the ninth interlayer insulating film INS9. The tenth interlayer insulating film INS10 may be disposed or provided between the reflective electrodes RL adjacent to each other. The tenth interlayer insulating film INS10 may be a film to flatten a stepped portion caused by the reflective electrodes RL. The eleventh interlayer insulating film INS11 may be disposed or provided on the tenth interlayer insulating film INS10 and the reflective electrodes RL.

The tenth interlayer insulating film INS10 and the eleventh interlayer insulating film INS11 may be of a silicon oxide (e.g., SiOₓ, wherein 0<X≤2; e.g., SiO₂)-based inorganic film, but embodiments of the present disclosure are not limited thereto.

The eleventh interlayer insulating film INS11 may be an optical auxiliary layer to adjust the resonance distance of light emitted from the light emitting stack IL in at least one selected from among the first sub-pixel SP1, the second sub-pixel SP2, and/or the third sub-pixel SP3. The thickness of the eleventh interlayer insulating film INS11 may be different in the first sub-pixel SP1, the second sub-pixel SP2, and the third sub-pixel SP3. For example, in order to adjust a distance from the reflective electrode RL to the second electrode CAT according to a main or predominant wavelength of light emitted from each of the first sub-pixel SP1, the second sub-pixel SP2, and the third sub-pixel SP3, the thickness of the eleventh interlayer insulating film INS11 may be set or predetermined for each of the first sub-pixel SP1, the second sub-pixel SP2, and the third sub-pixel SP3.

For example, as illustrated in FIG. 9, the thickness of the eleventh interlayer insulating film INS11 in the first sub-pixel SP1 may be greater than the thickness of the eleventh interlayer insulating film INS11 in the second sub-pixel SP2, and the thickness of the eleventh interlayer insulating film INS11 in the second sub-pixel SP2 may be greater than the thickness of the eleventh interlayer insulating film INS11 in the third sub-pixel SP3. In one or more embodiments, the distance between the first electrode AND and the reflective electrode RL in the first sub-pixel SP1 may be greater than the distance between the first electrode AND and the reflective electrode RL in the second sub-pixel SP2. In one or more embodiments, the distance between the first electrode AND and the reflective electrode RL in the second sub-pixel SP2 may be greater than the distance between the first electrode AND and the reflective electrode RL in the third sub-pixel SP3.

Each of the tenth vias VA10 may penetrate the eleventh interlayer insulating film INS11 and be connected to the exposed fourth reflective electrode RL4. The tenth vias VA10 may be of any one of copper (Cu), aluminum (Al), tungsten (W), molybdenum (Mo), chromium (Cr), gold (Au), titanium (Ti), nickel (Ni), and neodymium (Nd), or an alloy including any one selected from among them. The thickness of the tenth via VA10 in the first sub-pixel SP1 may be greater than the thickness of the tenth via VA10 in the second sub-pixel SP2, and the thickness of the tenth via VA10 in the second sub-pixel SP2 may be greater than the thickness of the tenth via VA10 in the third sub-pixel SP3.

The first electrode AND of each of the light emitting elements LE may be disposed or provided on the eleventh interlayer insulating film INS11 and connected to the tenth via VA10. The first electrode AND of each of the light emitting elements LE may be connected to the drain region DA or source region SA of the pixel transistor PTR through the tenth via VA10, the reflective electrode RL, the first via VA1 to the ninth via VA9, the first metal layer ML1 to the eighth metal layer ML8, and the contact terminal CTE. The first electrode AND of each of the light emitting elements LE may be of any one of copper (Cu), aluminum (Al), tungsten (W), molybdenum (Mo), chromium (Cr), gold (Au), titanium (Ti), nickel (Ni), and neodymium (Nd), or an alloy including any one selected from among them. For example, the first electrode AND of each of the light emitting elements LE may be titanium nitride (e.g., TiN_{X}, wherein 0<X≤2; e.g., TiN).

The pixel defining film PDL may be disposed or provided on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3. Each of the first emission area EA1, the second emission area EA2, and the third emission area EA3 may be an area where the light emitting element LE including the first electrode AND, the light emitting stack IL, and the second electrode CAT is disposed or provided.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include a first pixel defining film PDL1, a second pixel defining film PDL2, and a third pixel defining film PDL3. The first pixel defining film PDL1 may be disposed or provided on the edge of the first electrode AND of each of the light emitting elements LE, the second pixel defining film PDL2 may be disposed or provided on the first pixel defining film PDL1, and the third pixel defining film PDL3 may be disposed or provided on the second pixel defining film PDL2. The first pixel defining film PDL1, the second pixel defining film PDL2, and the third pixel defining film PDL3 may be of a silicon oxide (e.g., SiOₓ, wherein 0<X≤2; e.g., SiO₂)-based inorganic film. In one or more embodiments, the first pixel defining film PDL1 and the third pixel defining film PDL3 may be of a silicon nitride (e.g., Si₃N₄ or SiNₓ, wherein 0<X≤2)-based inorganic film, whereas the second pixel defining film PDL2 may be of a silicon oxide (e.g., SiOₓ, wherein 0<X≤2; e.g., SiO₂)-based inorganic film. The first pixel defining film PDL1, the second pixel defining film PDL2, and the third pixel defining film PDL3 may each have a thickness of about 500 Å.

In order to reduce or prevent the likelihood of the first encapsulation inorganic film TFE1 being cut off due to the step coverage, the first pixel defining film PDL1, the second pixel defining film PDL2, and the third pixel defining film PDL3 may have a cross-sectional structure having a stepped portion. Step coverage refers to the ratio of the degree of thin film coated on an inclined portion to the degree of thin film coated on a flat portion. The lower the step coverage, the more likely it is that the thin film will be cut off at inclined portions.

Each of the plurality of trenches TRC may penetrate the first pixel defining film PDL1, the second pixel defining film PDL2, and the third pixel defining film PDL3. The eleventh interlayer insulating film INS11 may be partially recessed at each of the plurality of trenches TRC.

At least one trench TRC may be disposed or provided between the neighboring sub-pixels SP1, SP2, and SP3. Although FIG. 9 illustrates that two trenches TRC are disposed or provided between the neighboring sub-pixels SP1, SP2, and SP3, embodiments of the present disclosure are not limited thereto.

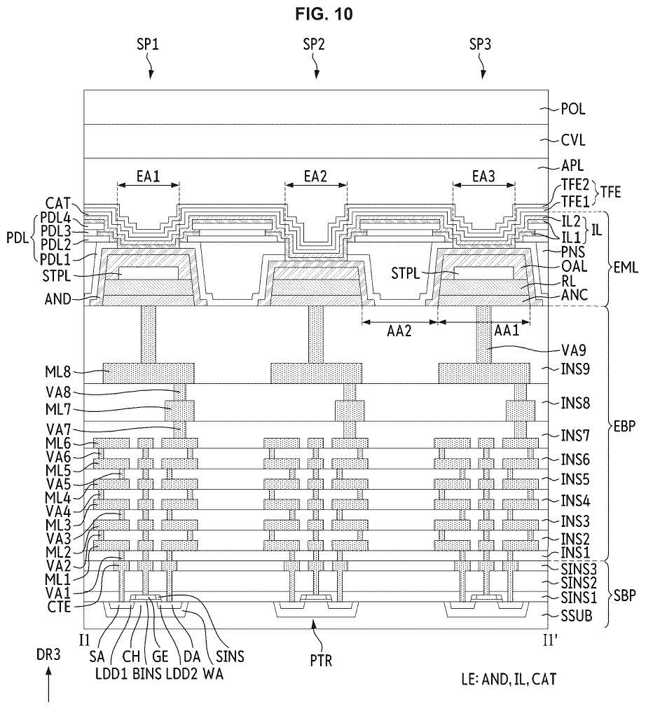

The light emitting stack IL may include a plurality of stack layers IL1, IL2, and IL3. FIG. 9 illustrates that the light emitting stack IL has a three-tandem structure including a first stack layer IL1, a second stack layer IL2, and a third stack layer IL3, but embodiments of the present disclosure are not limited thereto. For example, the light emitting stack IL may have a two-tandem structure including two stack layers as illustrated in FIG. 10.

In the three-tandem structure, the light emitting stack IL may have a tandem structure including a plurality of intermediate layers IL1, IL2, and IL3 that emit different lights. For example, the light emitting stack IL may include the first stack layer IL1 that emits first light, the second stack layer IL2 that emits second light, and the third stack layer IL3 that emits third light. The first stack layer IL1, the second stack layer IL2, and the third stack layer IL3 may be sequentially stacked.

The first stack layer IL1 may have a structure in which a first hole transport layer, a first light emitting layer that emits the first light, and a first electron transport layer are sequentially stacked. The second stack layer IL2 may have a structure in which a second hole transport layer, a second light emitting layer that emits the second light, and a second electron transport layer are sequentially stacked. The third stack layer IL3 may have a structure in which a third hole transport layer, a third light emitting layer that emits the third light, and a third electron transport layer are sequentially stacked.

A first charge generation layer to supply charges to the second stack layer IL2 and supply electrons to the first stack layer IL1 may be disposed or provided between the first stack layer IL1 and the second stack layer IL2. The first charge generation layer may include an N-type or kind charge generation layer that supplies electrons to the first stack layer IL1 and a P-type or kind charge generation layer that supplies holes to the second stack layer IL2. The N-type or kind charge generation layer may include a dopant of a metal material.

A second charge generation layer to supply charges to the third stack layer IL3 and supply electrons to the second stack layer IL2 may be disposed or provided between the second stack layer IL2 and the third stack layer IL3. The second charge generation layer may include an N-type or kind charge generation layer that supplies electrons to the second stack layer IL2 and a P-type or kind charge generation layer that supplies holes to the third stack layer IL3.

The first stack layer IL1 may be disposed or provided on the first electrodes AND and the pixel defining film PDL, and a residual film RIL disposed or provided on the bottom surface of each trench TRC may be substantially the same material as the first stack layer IL1. Due to the trench TRC, the first stack layer IL1 may be cut off between the neighboring sub-pixels SP1, SP2, and SP3. The second stack layer IL2 may be disposed or provided on the first stack layer IL1. Due to the trench TRC, the second stack layer IL2 may be cut off between the neighboring sub-pixels SP1, SP2, and SP3. A cavity ESS or an empty space may be disposed or provided between the residual film IL and the second stack layer IL2 in the trench TRC. The third stack layer IL3 may be disposed or provided on the second stack layer IL2. The third stack layer IL3 may not be cut off by the trench TRC and may be disposed or provided to cover the second stack layer IL2 in each of the trenches TRC.

In the three-tandem structure, each of the plurality of trenches TRC may be a structure to cut off the first hole transport layer to the third hole transport layer, the first charge generation layer, and the second charge generation layer of the first stack layer IL1, the second stack layer IL2, and the third stack layer IL3 of the display element layer EML between the neighboring sub-pixels SP1, SP2, and SP3. In one or more embodiments, in the two-tandem structure, each of the plurality of trenches TRC may be a structure to cut off the charge generation layer and the lower stack layer disposed or provided between the lower stack layer and the upper stack layer.

In order to stably cut off the first stack layer IL1 and the second stack layer IL2 of the display element layer EML between the neighboring sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. In order to cut off the charge generation layers and the hole transport layers of the light emitting stack IL of the display element layer EML between the neighboring sub-pixels SP1, SP2, and SP3, a different structure may be present instead of the trench TRC. For example, instead of the trench TRC, a reverse tapered partition wall may be disposed or provided on the pixel defining film PDL.

In one or more embodiments, FIG. 9 illustrates that the light emitting stack IL that emits light is disposed or provided in the first emission area EA1, the second emission area EA2, and the third emission area EA3, but embodiments of the present disclosure are not limited thereto. For example, instead of the light emitting stack IL, the first light emitting layer may be disposed or provided in the first emission area EA1 and may not be disposed or provided in the second emission area EA2 and the third emission area EA3. Furthermore, the second light emitting layer may be disposed or provided in the second emission area EA2 and may not be disposed or provided in the first emission area EA1 and the third emission area EA3.

Furthermore, the third light emitting layer may be disposed or provided in the third emission area EA3 and may not be disposed or provided in the first emission area EA1 and the second emission area EA2. In one or more embodiments, a first color filter CF1, a second color filter CF2, and a third color filter CF3 of the optical layer OPL may not be disposed or provided.

The second electrode CAT may be disposed or provided on the light emitting stack IL. For example, the second electrode CAT may be disposed or provided on the third stack layer IL3. The second electrode CAT may be of a transparent (e.g., substantially transparent) conductive (e.g., electrically conductive) material (TCO), such as ITO and/or IZO, that may transmit light or a semi-transmissive conductive (e.g., electrically conductive) material, such as magnesium (Mg), silver (Ag), or an alloy of Mg and Ag. If (e.g., when) the second electrode CAT is of a semi-transmissive conductive (e.g., electrically conductive) material, the light emission efficiency or suitably may be improved or enhanced in each of the first sub-pixel SP1, the second sub-pixel SP2, and the third sub-pixel SP3 due to a micro-cavity effect.

The encapsulation layer TFE may be disposed or provided on the display element layer EML. The encapsulation layer TFE may include at least one inorganic film TFE1 and TFE3 to prevent oxygen and/or moisture from permeating into the display element layer EML (or to reduce a degree to or occurrence of which oxygen and/or moisture permeate into the display element layer EML). The first encapsulation inorganic film TFE1 may be disposed or provided on the second electrode CAT, and the second encapsulation inorganic film TFE3 may be disposed or provided above the first encapsulation inorganic film TFE1. The first encapsulation inorganic film TFE1 and the second encapsulation inorganic film TFE3 may be of two or more layers in which one or more inorganic films of silicon nitride (e.g., Si₃N₄ or SiNₓ, wherein 0<X≤2), silicon oxynitride (e.g., Si₂N₂O or SiO_{X}N_{Y}, wherein 0<X≤2 and 0≤Y≤2; e.g., SiON), silicon oxide (e.g., SiOₓ, wherein 0<X≤2; e.g., SiO₂), titanium oxide (e.g., TiOₓ, wherein 0<X≤2; e.g., TiO₂), and aluminum oxide (e.g., Al₂O₃) layers are alternately stacked.

In one or more embodiments, the encapsulation layer TFE may include at least one organic film TFE2 to protect the display element layer EML from foreign substances, such as dust. The encapsulating organic film TFE2 may be disposed or provided between the first encapsulating inorganic film TFE1 and the second encapsulating inorganic film TFE3. The encapsulation organic film TFE2 may be a monomer. In one or more embodiments, the encapsulation organic film TFE2 may be an organic film, such as an acryl resin, an epoxy resin, a phenolic resin, a polyamide resin, a polyimide resin and/or the like.

An adhesive layer ADL may be a layer to bond the encapsulation layer TFE to the optical layer OPL. The adhesive layer ADL may be a double-sided adhesive member. In one or more embodiments, the adhesive layer ADL may be a transparent (e.g., substantially transparent) adhesive member, such as a transparent (e.g., substantially transparent) adhesive and/or a transparent (e.g., substantially transparent) adhesive resin.

The optical layer OPL may include a plurality of color filters CF1, CF2, and CF3, a plurality of lenses LNS, and a filling layer FIL. The plurality of color filters CF1, CF2, and CF3 may include the first color filter CF1, the second color filter CF2, and the third color filter CF3. The first color filter CF1, the second color filter CF2, and the third color filter CF3 may be disposed or provided on the adhesive layer ADL.

The first color filter CF1 may overlap the first emission area EA1 of the first sub-pixel SP1. The first color filter CF1 may transmit light of the first color, e.g., light of a blue wavelength band. The blue wavelength band may be about 370 nm to about 460 nm. Thus, the first color filter CF1 may transmit light of the first color among light emitted from the first emission area EA1.

The second color filter CF2 may overlap the second emission area EA2 of the second sub-pixel SP2. The second color filter CF2 may transmit light of the second color, e.g., light of a green wavelength band. The green wavelength band may be about 480 nm to about 560 nm. Thus, the second color filter CF2 may transmit light of the second color among light emitted from the second emission area EA2.

The third color filter CF3 may overlap the third emission area EA3 of the third sub-pixel SP3. The third color filter CF3 may transmit light of the third color, e.g., light of a red wavelength band. The red wavelength band may be about 600 nm to about 750 nm. Thus, the third color filter CF3 may transmit light of the third color among light emitted from the third emission area EA3.

The plurality of lenses LNS may be disposed or provided on the first color filter CF1, the second color filter CF2, and the third color filter CF3, respectively.

Each of the plurality of lenses LNS may be a structure to increase the proportion of light directed to the front of the display device 10. Each of the plurality of lenses LNS may have a cross-sectional shape that is convex in an upward direction.

The filling layer FIL may be disposed or provided on the plurality of lenses LNS. The filling layer FIL may have a set or predetermined refractive index such that light travels in the third direction DR3 at an interface between the filling layer FIL and the plurality of lenses LNS. Further, the filling layer FIL may be a planarization layer. The filling layer FIL may be an organic film, such as an acrylic resin, an epoxy resin, a phenolic resin, a polyamide resin, and/or a polyimide resin.

The cover layer CVL may be disposed or provided on the filling layer FIL. The cover layer CVL may be a glass substrate and/or a polymer resin. If (e.g., when) the cover layer CVL is a glass substrate, it may be attached onto the filling layer FIL. In one or more embodiments, the filling layer FIL may serve to bond the cover layer CVL. If (e.g., when) the cover layer CVL is a glass substrate, it may serve as an encapsulation substrate. If (e.g., when) the cover layer CVL is a polymer resin, it may be directly applied onto the filling layer FIL.

The polarizing plate may be disposed or provided on one surface of the cover layer CVL. The polarizing plate may be a structure to reduce or prevent visibility degradation caused by reflection of external light. The polarizing plate may include a linear polarizing plate and a phase retardation film. For example, the phase retardation film may be a λ/4 plate (quarter-wave plate), but embodiments of the present disclosure are not limited thereto. However, if (e.g., when) visibility degradation caused by reflection of external light is sufficiently or suitably overcome by the first color filter CF1, the second color filter CF2, and the third color filter CF3, the polarizing plate may not be disposed or provided.

FIG. 10 is a schematic cross-sectional view illustrating another example of the display panel taken along the line I1-I1′ as illustrated in FIG. 7.

The embodiment of FIG. 10 differs from the embodiment of FIG. 9 in that the first electrode AND of each of the light emitting elements LE is in contact with and electrically connected to the side surface of a connection electrode ANC connected to the eighth conductive layer ML8. The embodiment of FIG. 10 also differs from the embodiment of FIG. 9 in that the trench TRC is not provided, and instead, the third pixel defining film PDL3 and a fourth pixel defining film PDL4 have an eave-shaped (e.g., substantially eave-shaped) or mushroom-shaped (e.g., substantially mushroom-shaped) cross-sectional structure. In the embodiment of FIG. 10, redundant description of parts already described in the embodiment of FIG. 9 may not be provided.

Referring to FIG. 10, the plurality of connection electrodes ANC may be respectively disposed or provided on first portions AA1 of the ninth interlayer insulating film INS9. Each of the plurality of connection electrodes ANC may be disposed or provided on the first portion AA1 of the ninth interlayer insulating film INS9 that corresponds thereto. A plurality of connection electrodes ANC may be of any one of copper (Cu), aluminum (Al), tungsten (W), molybdenum (Mo), chromium (Cr), gold (Au), titanium (Ti), nickel (Ni), and neodymium (Nd), an alloy including any one selected from among them, or a transparent (e.g., substantially transparent) conductive (e.g., electrically conductive) oxide. For example, the plurality of connection electrodes ANC may include titanium (Ti), titanium nitride (e.g., TiN_{X}, wherein 0<X≤2; e.g., TiN), indium tin oxide (ITO), or indium zinc oxide (IZO), but embodiments of the present disclosure are limited thereto.

A plurality of reflective electrodes RL may be respectively disposed or provided on the plurality of connection electrodes ANC. Each of the plurality of reflective electrodes RL may be disposed or provided on the connection electrode ANC that corresponds thereto. The plurality of reflective electrodes RL may be of any one of copper (Cu), aluminum (Al), tungsten (W), molybdenum (Mo), chromium (Cr), gold (Au), titanium (Ti), nickel (Ni), and neodymium (Nd), or an alloy including any one selected from among them. For example, each of the plurality of reflective electrodes RL may include aluminum (Al) having relatively high reflectivity.

A plurality of optical auxiliary films OAL may be respectively disposed or provided on the plurality of reflective electrodes RL. Each of the plurality of optical auxiliary films OAL may be disposed or provided on the reflective electrode RL that corresponds thereto. The plurality of optical auxiliary films OAL may be of a silicon oxide (e.g., SiOₓ, wherein 0<X≤2; e.g., SiO₂)-based inorganic film, but embodiments of the present disclosure are not limited thereto.

In each of the first emission area EA1 and the third emission area EA3, a step layer STPL may be disposed or provided on the reflective electrode RL, and the optical auxiliary film OAL may be disposed or provided on the step layer STPL. In the second emission area EA2, only the optical auxiliary film OAL may be disposed or provided on the reflective electrode RL. The thicknesses of the optical auxiliary film OAL may be substantially the same in the first emission area EA1, the second emission area EA2, and the third emission area EA3.

Due to the step layer STPL, the distance between the reflective electrode RL and the first electrode AND in the first emission area EA1 and the third emission area EA3 may be greater than the distance between the reflective electrode RL and the first electrode AND in the second emission area EA2. The thickness of the step layer STPL and the thickness of the optical auxiliary layer OAL may be set or predetermined in consideration of the wavelength and resonance distance of light emitted from the first stack layer IL1 of the light emitting stack IL and the wavelength and resonance distance of light emitted from the second stack layer IL2 thereof.

Each of the light emitting elements LE may include the first electrode AND, a light emitting stack IL, and a second electrode CAT.

The first electrode AND of each of the light emitting elements LE may be disposed or provided on the optical auxiliary film OAL that corresponds thereto. Because the connection electrode ANC, the reflective electrode RL, and the optical auxiliary layer OAL are sequentially stacked, the first electrode AND of each of the light emitting elements LE may be disposed or provided on the top surface and the side surface of the optical auxiliary layer OAL, the side surface of the reflective electrode RL, and the side surface of the connection electrode ANC. Accordingly, the first electrode AND of each of the light emitting elements LE may be in contact with and electrically connected to the side surface of the reflective electrode RL and the side surface of the connection electrode ANC. Therefore, compared to if (e.g., when) the first electrode AND of each of the light emitting elements LE is connected to the reflective electrode RL exposed through a through hole that penetrates the optical auxiliary film OAL, the number of mask processes may be reduced, thereby lowering manufacturing cost and increasing or enhancing manufacturing efficiency.

The first electrode AND of each of the light emitting elements LE may be connected to the drain region DA or the source region SA of the pixel transistor PTR through the connection electrode ANC, the first via VA1 to the ninth via VA9, the first conductive layer ML1 to the eighth conductive layer ML8, and the contact terminal CTE.

The ninth interlayer insulating film INS9 may include the first portion AA1 that overlaps the connection electrode ANC in the third direction DR3 and a second portion AA2 that does not overlap the connection electrode ANC in the third direction DR3. The thickness of the first portion AA1 and the thickness of the second portion AA2 of the ninth interlayer insulating film INS9 may be substantially the same.

In one or more embodiments, the thickness of the first portion AA1 of the ninth interlayer insulating film INS9 may be greater than the thickness of the second portion AA2 thereof. In one or more embodiments, the side surface of the first portion AA1 of the ninth interlayer insulating film INS9 may be exposed, and the first electrode AND of each of the light emitting elements LE may be disposed or provided on the exposed side surface of the first portion AA1 of the ninth interlayer insulating film INS9.

The first electrode AND of each of the light emitting elements LE may be of any one of copper (Cu), aluminum (Al), tungsten (W), molybdenum (Mo), chromium (Cr), gold (Au), titanium (Ti), nickel (Ni), and neodymium (Nd), an alloy including any one selected from among them, or a transparent (e.g., substantially transparent) conductive (e.g., electrically conductive) oxide. For example, the first electrode AND of each of the light emitting elements LE may include titanium (Ti), titanium nitride (e.g., TiN_{X}, wherein 0<X≤2; e.g., TiN), indium tin oxide (ITO), or indium zinc oxide (IZO), but embodiments of the present disclosure are limited thereto.

The pixel defining film PDL may be disposed or provided on a part of the first electrode AND of each of the light emitting elements LE. The pixel defining film PDL may cover the edge of the first electrode AND of each of the light emitting elements LE. The pixel defining film PDL may partition the first emission areas EA1, the second emission areas EA2, and the third emission areas EA3.

The pixel defining film PDL may include a first pixel defining film PDL1, a second pixel defining film PDL2, a third pixel defining film PDL3, and a fourth pixel defining film PDL4.

The first pixel defining film PDL1 may be disposed or provided on the first electrode AND of each of the light emitting elements LE. For example, the first pixel defining film PDL1 may cover a part of the top surface of the first electrode AND disposed or provided on the optical auxiliary film OAL. Further, the first pixel defining film PDL1 may cover the first electrode AND disposed or provided on the side surface of the connection electrode ANC, the side surface of the reflective electrode RL, and the side surface of the optical auxiliary film OAL. The first pixel defining film PDL1 may be disposed or provided on the top surface of the second portion AA2 of the ninth interlayer insulating film INS9.

A planarization film PNS may be a film to flatten the stepped portion caused by the connection electrode ANC, the reflective electrode RL, and the optical auxiliary film OAL.

The planarization film PNS may be disposed or provided on the first pixel defining film PDL1 that covers the first electrode AND disposed or provided on the side surface of the connection electrode ANC, the side surface of the reflective electrode RL, and the side surface of the optical auxiliary film OAL. The planarization film PNS may be disposed or provided on the first pixel defining film PDL1 disposed or provided on the second portion AA2 of the ninth interlayer insulating film INS9.

The planarization film PNS may be disposed or provided between the connection electrodes ANC adjacent in the first direction DR1 or the second direction DR2. The planarization film PNS may be disposed or provided between the reflective electrodes RL adjacent in the first direction DR1 or the second direction DR2. The planarization film PNS may be disposed or provided between the optical auxiliary films OAL adjacent in the first direction DR1 or the second direction DR2.

The step layer STPL may not be present in the second emission area EA2, whereas the step layer STPL may be present in each of the first emission area EA1 and the third emission area EA3. Accordingly, the heights of the connection electrode ANC, the reflective electrode RL, and the optical auxiliary film OAL in the second emission area EA2 may be less than the heights of the connection electrode ANC, the reflective electrode RL, the step layer STPL, and the optical auxiliary film OAL in the first emission area EA1 and the third emission area EA3. Therefore, the planarization film PNS may cover the top surface of the first pixel defining film PDL1 disposed or provided on the top surface of the first electrode AND disposed or provided in the second emission area EA2.

In contrast, the top surface of the planarization film PNS may be flatly connected to the top surface of the first pixel defining film PDL1 disposed or provided on the top surface of the first electrode AND disposed or provided in the first emission area EA1 and the third emission area EA3. For example, the planarization film PNS may not cover the top surface of the first pixel defining film PDL1 disposed or provided on the top surface of the first electrode AND disposed or provided in each of the first emission area EA1 and the third emission area EA3.

The second pixel defining film PDL2 may be disposed or provided on the first pixel defining film PDL1 and the planarization film PNS, the third pixel defining film PDL3 may be disposed or provided on the second pixel defining film PDL2, and the fourth pixel defining film PDL4 may be disposed or provided on the third pixel defining film PDL3. The first pixel defining film PDL1 and the third pixel defining film PDL3 may be of a silicon nitride (e.g., Si₃N₄ or SiNₓ, wherein 0<X≤2)-based inorganic film, whereas the second pixel defining film PDL2, the fourth pixel defining film PDL4, and the planarization film PNS may be of a silicon oxide (e.g., SiOₓ, wherein 0<X≤2; e.g., SiO₂)-based inorganic film. The first pixel defining film PDL1 may be of a material different from that of the planarization film PNS, and thus may serve as a stopper in a chemical mechanical polishing process for the planarization film PNS.

If (e.g., when) the planarization film PNS and the second pixel defining film PDL2 are both (e.g., simultaneously) formed or provided as a silicon oxide (e.g., SiOₓ, wherein 0<X≤2; e.g., SiO₂)-based inorganic film, the planarization film PNS and the second pixel defining film PDL2 may be formed or provided as a single film.

Because the length of the third pixel defining film PDL3 in one direction is less than the length of the fourth pixel defining film PDL4 in one direction, the bottom surface of the fourth pixel defining film PDL4 may be exposed without being covered by the third pixel defining film PDL3. For example, the third pixel defining film PDL3 and the fourth pixel defining film PDL4 may have an eaves-shaped (e.g., substantially eaves-shaped) or mushroom-shaped (e.g., substantially mushroom-shaped) cross-sectional structure.

The light emitting stack IL may be disposed or provided on the first electrode AND and the pixel defining film PDL. The light emitting stack IL may include the first stack layer IL1 and the second stack layer IL2 that emit different lights. If (e.g., when) the light emitting stack IL has a two-tandem structure, one selected from the first stack layer IL1 and the second stack layer IL2 may emit light that includes the wavelength range of any one selected from among the first light, the second light, and the third light, and the other may emit light that includes the wavelength ranges of the other two lights. For example, the first stack layer IL1 may emit light that includes the wavelength range of the first light and the wavelength range of the third light, and the second stack layer IL2 may emit light that includes the wavelength range of the second light. Herein, the first light may be light of a blue wavelength band, the second light may be light of a green wavelength band, and the third light may be light of a red wavelength band.

A charge generation layer to supply charges to the second stack layer IL2 and supply electrons to the first stack layer IL1 may be disposed or provided between the first stack layer IL1 and the second stack layer IL2. The charge generation layer may include an n-type or kind charge generation layer that supplies electrons to the first stack layer IL1 and a p-type or kind charge generation layer that supplies holes to the second stack layer IL2. The N-type or kind charge generation layer may include a dopant of a metal material.

The first stack layer IL1 may not be formed or provided on the bottom surface of the fourth pixel defining film PDL4 that is exposed without being covered by the third pixel defining film PDL3, and thus may be cut off by the eaves-shaped (e.g., substantially eaves-shaped) or mushroom-shaped (e.g., substantially mushroom-shaped) cross-sectional structure of the third pixel defining film PDL3 and the fourth pixel defining film PDL4. In one or more embodiments, the first hole transport layer of the first stack layer IL1 and a charge generation layer that is disposed or provided between the first stack layer IL1 and the second stack layer IL2 may also be cut off. Further, although FIG. 10 illustrates that the second stack layer IL2 is connected without being cut off, the second hole transport layer of the second stack layer IL2 may be cut off, and the second electron transport layer of the second stack layer IL2 may be connected without being cut off. Therefore, it is feasible to prevent a leakage current from flowing (or reduce a degree to or occurrence of which a leakage current flows) through the first hole transport layer of the first stack layer IL1, the second hole transport layer of the second stack layer IL2, and the charge generation layer between the adjacent emission areas EA1, EA2, and EA3. Accordingly, it is feasible to prevent the light emitting stack IL in the adjacent emission areas EA1, EA2, and EA3 from emitting light other than the originally intended light (or reduce a degree to or occurrence of which the light emitting stack IL in the adjacent emission areas EA1, EA2, and EA3 emits light other than the originally intended light) due to the influence of the current as described in one or more embodiments.

Although FIG. 10 illustrates a two-tandem structure in which the light emitting stack IL includes two stack layers IL1 and IL2, embodiments of the present disclosure are not limited thereto. For example, the light emitting stack IL may have a three-tandem structure including three stack layers as illustrated in FIG. 9. In one or more embodiments, it may be designed such that the charge generation layer between the first stack layer IL1 and the second stack layer IL2 and the charge generation layer between the second stack layer IL2 and the third stack layer IL3 are cut off by adjusting the height of the third pixel defining film PDL3. In one or more embodiments, as illustrated in FIG. 9, the trench TRC that penetrates the first pixel defining film PDL1, the planarization film PNS, the second pixel defining film PDL2, and the third pixel defining film PDL3 may be added. In one or more embodiments, the trench TRC may penetrate at least a part of the ninth interlayer insulating film INS9, but embodiments of the present disclosure are not limited thereto.

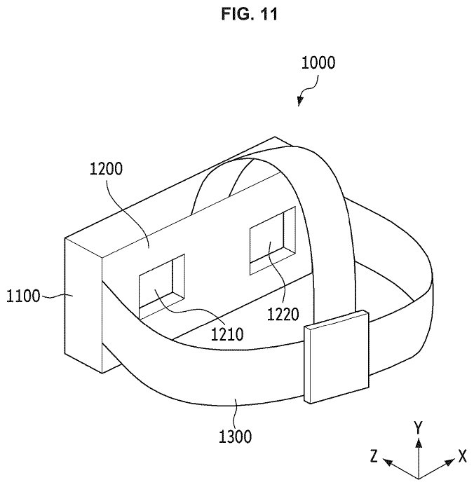

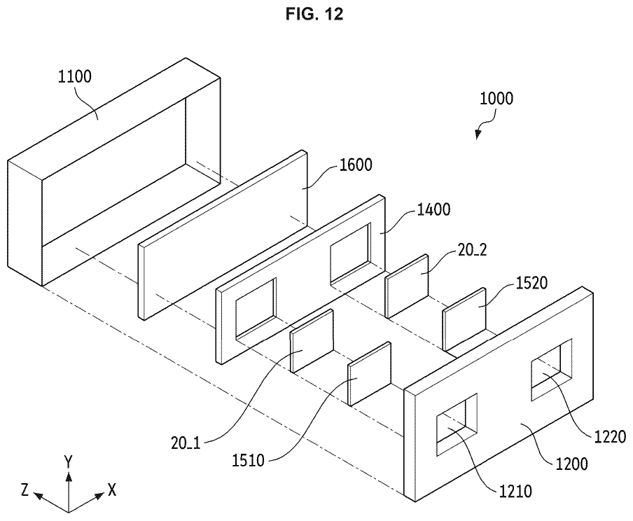

FIG. 11 is a schematic perspective view illustrating one example of a head mounted display. FIG. 12 is a schematic exploded perspective view illustrating the head mounted display as illustrated in FIG. 11.

Referring to FIGS. 11 and 12, a head mounted display 1000 according to one or more embodiments may include a first display device 20_1, a second display device 20_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 20_1 may provide an image to the user's left eye, and the second display device 20_2 may provide an image to the user's right eye.

Because each of the first display device 20_1 and the second display device 20_2 is substantially the same as the display device 20 as described in conjunction with FIGS. 3 to 10, the description of the first display device 20_1 and the second display device 20_2 may not be provided.

The first optical member 1510 may be disposed or provided between the first display device 20_1 and the first eyepiece 1210. The second optical member 1520 may be disposed or provided between the second display device 20_2 and the second eyepiece 1220. Each of the first optical member 1510 and the second optical member 1520 may include at least one convex lens.

The middle frame 1400 may be disposed or provided between the first display device 20_1 and the control circuit board 1600 and between the second display device 20_2 and the control circuit board 1600. The middle frame 1400 may serve to support and fix the first display device 20_1, the second display device 20_2, and the control circuit board 1600.

The control circuit board 1600 may be disposed or provided between the middle frame 1400 and the display device housing 1100. The control circuit board 1600 may be connected to the first display device 20_1 and the second display device 20_2 through the connector. The control circuit board 1600 may convert an image source inputted from the outside into the digital video data DATA and transmit the digital video data DATA to the first display device 20_1 and the second display device 20_2 through the connector.

The control circuit board 1600 may transmit the digital video data DATA that corresponds to a left-eye image optimized for the user's left eye to the first display device 20_1 and may transmit the digital video data DATA that corresponds to a right-eye image optimized for the user's right eye to the second display device 20_2. In one or more embodiments, the control circuit board 1600 may transmit substantially the same digital video data DATA to the first display device 20_1 and the second display device 20_2.

The display device housing 1100 may serve to accommodate the first display device 20_1, the second display device 20_2, the middle frame 1400, the first optical member 1510, the second optical member 1520, and the control circuit board 1600. The housing cover 1200 may be disposed or provided to cover one open surface of the display device housing 1100. The housing cover 1200 may include the first eyepiece 1210 at which the user's left eye is located and the second eyepiece 1220 at which the user's right eye is located. FIGS. 11 and 12 illustrate that the first eyepiece 1210 and the second eyepiece 1220 are disposed or provided separately, but embodiments of the present disclosure are not limited thereto. The first eyepiece 1210 and the second eyepiece 1220 may be combined into one.

The first eyepiece 1210 may be aligned with the first display device 20_1 and the first optical member 1510, and the second eyepiece 1220 may be aligned with the second display device 20_2 and the second optical member 1520.

Therefore, the user may view, through the first eyepiece 1210, the image of the first display device 20_1 magnified as a virtual image by the first optical member 1510, and may view, through the second eyepiece 1220, the image of the second display device 20_2 magnified as a virtual image by the second optical member 1520.

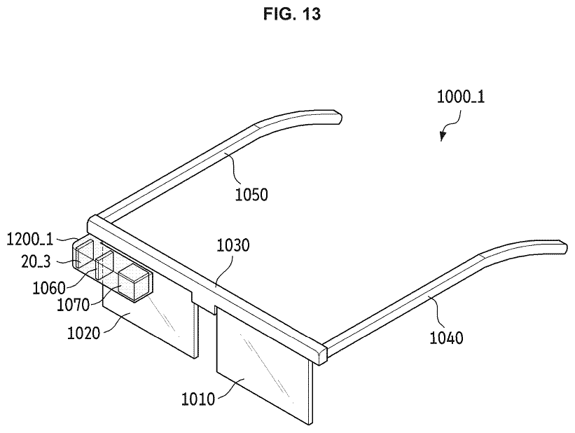

The head mounted band 1300 may serve to secure or provide the display device housing 1100 to the user's head such that the first eyepiece 1210 and the second eyepiece 1220 of the housing cover 1200 remain located on the user's left and right eyes, respectively. If (e.g., when) the display device housing 1200 is implemented to be lightweight and compact, the head mounted display 1000 may be provided with, as illustrated in FIG. 13, an eyeglass frame instead of the head mounted band 1300.

FIG. 13 is a schematic perspective view illustrating another example of a head mounted display.

Referring to FIG. 13, a head mounted display 1000_1 according to one or more embodiments may be an eyeglasses-type or kind display device in which a display device housing 1200_1 is implemented in a lightweight and compact manner. The head mounted display 1000_1 according to one or more embodiments may include a display device 20_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 20_3, the optical member 1060, and the optical path changing member 1070. The image displayed on the display device 20_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed on the display device 20_3 and a real image seen through the right eye lens 1020 are combined.

FIG. 13 illustrates that the display device housing 1200_1 may be disposed or provided at the right end of the support frame 1030, but embodiments of the present disclosure are not limited thereto. For example, the display device housing 1200_1 may be disposed or provided at the left end of the support frame 1030, and, in one or more embodiments, the image of the display device 20_3 may be provided to the user's left eye. In one or more embodiments, the display device housing 1200_1 may be disposed or provided at both (e.g., simultaneously) the left and right ends of the support frame 1030, and, in one or more embodiments, the user may view the image displayed on the display device 20_3 through both (e.g., simultaneously) the left and right eyes.

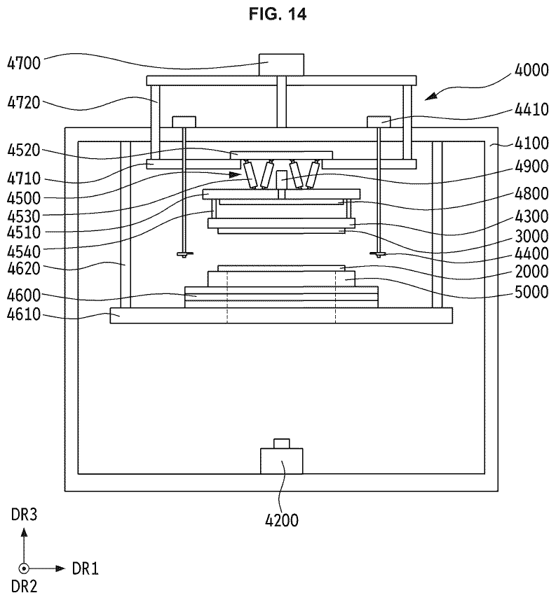

FIG. 14 is a schematic diagram illustrating a mask stage and a deposition apparatus including the mask stage according to one or more embodiments of the present disclosure.

Referring to FIG. 14, a mask stage 5000 and a deposition apparatus 4000 according to one or more embodiments of the present disclosure may be used to form or provide light emitting material layers on a backplane substrate 3000 in a manufacturing process for the display panel 100 (see FIG. 3). For example, as illustrated in FIG. 9, the semiconductor backplane SBP and the light emitting element backplane EBP may be disposed or provided on the backplane substrate 3000, and the reflective electrodes RL and the insulating films INS10 and INS11 may be disposed or provided on the light emitting element backplane EBP. Electrode patterns, for example, the anode electrodes AND may be disposed or provided on the insulating film INS11, and the anode electrodes AND may be electrically connected to the reflective electrodes RL through the vias VA10. As an example, the deposition apparatus 4000 may form or provide first light emitting layers on the anode electrodes AND of first emission areas EA1. As another example, the deposition apparatus 4000 may form or provide second light emitting layers on the anode electrodes AND of second emission areas EA2. As still another example, the deposition apparatus 4000 may form or provide third light emitting layers on the anode electrodes AND of third emission areas EA3.

The deposition apparatus 4000 may include a deposition source 4200 to provide a vapor deposition material on the backplane substrate 3000, the mask stage 5000 disposed or provided above the deposition source 4200 and on which a deposition mask 2000 is placed or provided, and a substrate chuck 4300 disposed or provided above the mask stage 5000 and configured or provided to support the backplane substrate 3000 such that the backplane substrate 3000 is opposite to (e.g., faces) the deposition mask 2000. For example, the substrate chuck 4300 may support the backplane substrate 3000 such that the front surface of the backplane substrate 3000 is opposite to (e.g., faces) downward and may locate or provide the backplane substrate 3000 above the deposition mask 2000 to perform a deposition process.

The deposition source 4200, the substrate chuck 4300, and the mask stage 5000 may be disposed or provided in a process chamber 4100. The process chamber 4100 may have an internal space, and a deposition process to form or provide deposition material layers on the backplane substrate 3000 may be performed in the internal space of the process chamber 4100. In one or more embodiments, the process chamber 4100 may be connected to a vacuum pump, and the internal space of the process chamber 4100 may be set or predetermined to a vacuum atmosphere by the vacuum pump. An opening to load or unload the backplane substrate 3000 and the deposition mask 2000 may be provided on one wall of the process chamber 4100, and the opening may be opened and closed by a gate valve.

A deposition material may be accommodated in the deposition source 4200. The deposition source 4200 may evaporate a deposition material, such as an organic material, an inorganic material, a conductive (e.g., electrically conductive) material, and/or the like toward the backplane substrate 3000, and the evaporated deposition material may be deposited on the backplane substrate 3000 through the deposition mask 2000. For example, the deposition source 4200 may evaporate an organic material to form or provide light emitting material layers on the backplane substrate 3000, and the evaporated organic material may be deposited on the electrode patterns on the backplane substrate 3000 through the deposition mask 2000.

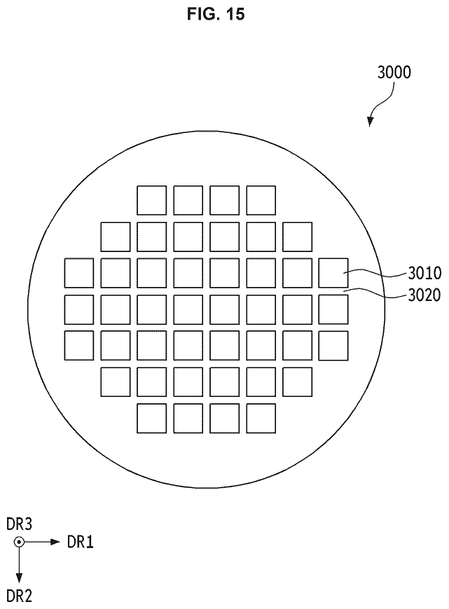

FIG. 15 is a schematic bottom view illustrating the backplane substrate as illustrated in FIG. 14.

Referring to FIG. 15, the backplane substrate 3000 may include a plurality of display cell regions 3010 and a scribe lane region 3020 disposed or provided between the display cell regions 3010. The display cell regions 3010 may be arranged or provided in a matrix form along the first direction DR1 and the second direction DR2 as illustrated in FIG. 15 and may be individualized into display panels 100 (see FIG. 3) by a dicing process after the display manufacturing process is completed. For example, the first direction DR1 may be a first horizontal direction, the second direction DR2 may be a second horizontal direction perpendicular (e.g., substantially perpendicular) to the first direction DR1, and each of the display cell regions 3010 may have a substantially rectangular shape.

For example, each of the display cell regions 3010 may include the semiconductor backplane SBP, the light emitting element backplane EBP disposed or provided on the semiconductor backplane SBP, the reflective electrodes RL disposed or provided on the light emitting element backplane EBP, and the insulating films INS10 and INS11 disposed or provided on the reflective electrodes RL as illustrated in FIG. 9. In one or more embodiments, each of the display cell regions 3010 may include the plurality of electrode patterns, for example, the plurality of anode electrodes AND disposed or provided on the insulating film INS11 and a pixel defining film PDL that exposes the anode electrodes AND, and the anode electrodes AND may be connected to the reflective electrodes RL through the plurality of vias VA10. In one or more embodiments, the electrode patterns of the display cell regions 3010 may be disposed or provided on the front surface of the backplane substrate 3000, and the substrate chuck 4300 may hold the rear surface of the backplane substrate 3000 such that the electrode patterns of the display cell regions 3010 face downward, e.g., face the deposition source 4200.

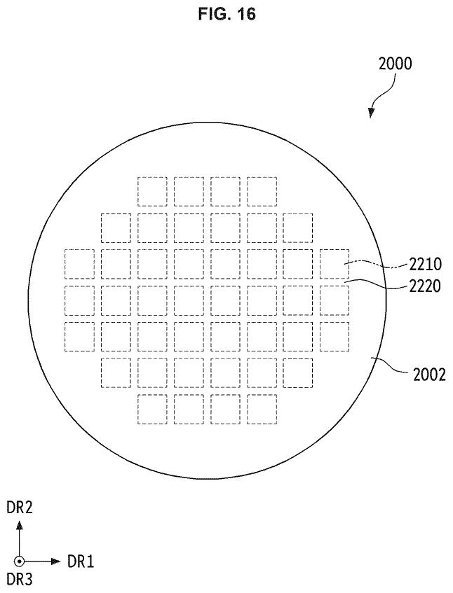

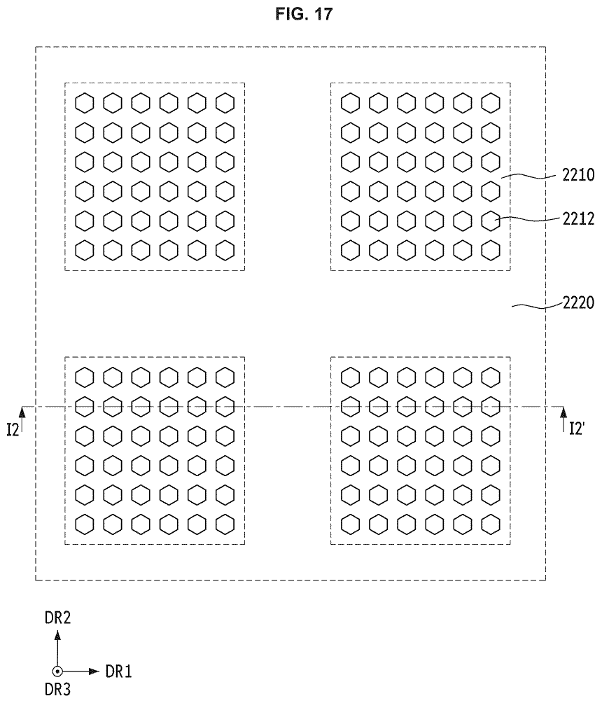

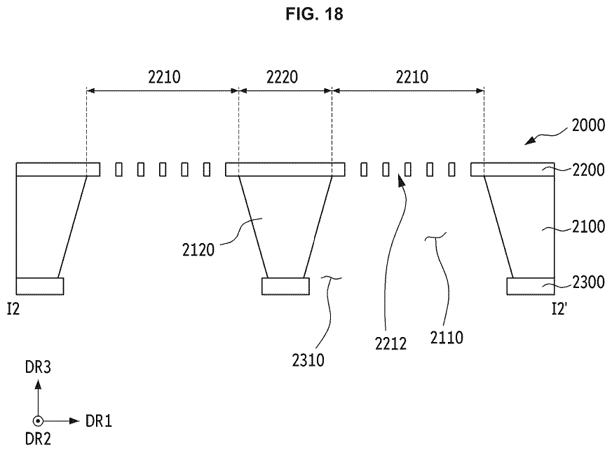

FIG. 16 is a schematic plan view illustrating the deposition mask as illustrated in FIG. 14. FIG. 17 is a schematic enlarged plan view illustrating the mask cell regions as illustrated in FIG. 16. FIG. 18 is a schematic cross-sectional view taken along the line I2-I2′ as illustrated in FIG. 17.

Referring to FIGS. 16 to 18, the deposition mask 2000 may include mask cell regions 2210 that respectively correspond to the display cell regions 3010 of the backplane substrate 3000. Each of the mask cell regions 2210 may have a plurality of pixel openings 2212 that expose the anode electrodes AND in the deposition process. For example, the deposition mask 2000 may include a mask frame 2100 and a membrane 2200 disposed or provided on the mask frame 2100. In one or more embodiments, the membrane 2200 may include the plurality of mask cell regions 2210, and each of the mask cell regions 2210 may have a plurality of pixel openings 2212.

For example, the mask frame 2100 may have cell openings 2110 and include a rib region 2120 that defines the cell openings 2110. The membrane 2200 may include the mask cell regions 2210 respectively disposed or provided on the cell openings 2110 and a grid region 2220 around (e.g., surrounding) the mask cell regions 2210. For example, the grid region 2220 of the membrane 2200 may be disposed or provided on the rib region 2120 of the mask frame 2100. The mask cell regions 2210 may be exposed toward the deposition source 4200 through the cell openings 2110, and the pixel openings 2212 may be formed or provided to penetrate the mask cell regions 2210. For example, the pixel openings 2212 may communicate with the cell openings 2110. In one or more embodiments, while performing the deposition process, the vapor deposition material provided from the deposition source 4200 may be deposited on the anode electrodes AND of the backplane substrate 3000 through the cell openings 2110 and the pixel openings 2212.

As illustrated in FIG. 16, the mask cell regions 2210 may be arranged or provided in a matrix form along the first direction DR1 and the second direction DR2. For example, the first direction DR1 may be the first horizontal direction, and the second direction DR2 may be the second horizontal direction perpendicular (e.g., substantially perpendicular) to the first direction DR1. In one or more embodiments, the third direction DR3 may be a vertical direction. For example, the third direction DR3 may be a direction perpendicular (e.g., substantially perpendicular) to the first direction DR1 and the second direction DR2. For example, the third direction DR3 may be a thickness direction of the mask frame 2100. The mask cell regions 2210 may have, for example, a substantially quadrilateral shape as illustrated in the drawing, and the pixel openings 2212 may be arranged to correspond to the anode electrodes AND of any one selected from among the first emission areas EA1, the second emission areas EA2, and the third emission areas EA3.

The membrane 2200 may be disposed or provided on the front surface of the mask frame 2100, and a rear inorganic film 2300 may be disposed or provided on the rear surface of the mask frame 2100. The rear inorganic film 2300 may have rear openings 2310 that expose the cell openings 2110 and may function as an etching mask in an etching process to form or provide the cell openings 2110.

For example, the membrane 2200 and the rear inorganic film 2300 may be made of an inorganic material, such as silicon nitride (e.g., Si₃N₄ or SiNₓ, wherein 0<X≤2) and may be formed or provided to have a thickness of about 0.5 μm to about 3 μm by a thermal chemical vapor deposition (TCVD) process. For example, the front inorganic film and the rear inorganic film 2300 may be simultaneously formed or provided on the front surface and the rear surface of the mask frame 2100 by the TCVD process, respectively, and the front inorganic film may be used as the membrane 2200.

A single crystal silicon substrate may be used as the mask frame 2100, and the pixel openings 2212 may be formed or provided by forming or providing the membrane 2200 on the front surface of the mask frame 2100 and then patterning the membrane 2200. For example, the pixel openings 2212 may be formed or provided by forming or providing a photoresist pattern that exposes portions where the pixel openings 2212 are to be formed or provided on the membrane 2200, and then performing an anisotropic etching process utilizing the photoresist pattern as an etching mask until the front surface of the mask frame 2100 is exposed.

The rear openings 2310 may be formed or provided by forming or providing the rear inorganic film 2300 on the rear surface of the mask frame 2100 and then patterning the rear inorganic film 2300. For example, the rear openings 2310 may be formed or provided by forming or providing a photoresist pattern that exposes portions where the rear openings 2310 are to be formed or provided on the rear inorganic film 2300, and then performing an anisotropic etching process utilizing the photoresist pattern as an etching mask until the rear surface of the mask frame 2100 is exposed.

The cell openings 2110 may be formed or provided to expose the pixel openings 2212 of the membrane 2200 through an anisotropic etching process utilizing the rear inorganic film 2300 as an etching mask. By way of example, the cell openings 2110 may be formed or provided through a wet etching process using tetramethylammonium hydroxide (TMAH) and/or potassium hydroxide (KOH). In one or more embodiments, the <100> crystal direction of the single crystal silicon substrate used as the mask frame 2100 may be the third direction DR3, and, accordingly, the cell openings 2110 may be formed or provided by the wet etching process to have a width that gradually decreases toward the membrane 2200, e.g., in the third direction DR3. For example, each of the inner surfaces of the cell openings 2110 may be formed or provided to have an inclination of about 54.74°.

Referring again to FIG. 14, the substrate chuck 4300 may be disposed or provided above the mask stage 5000 and may support the backplane substrate 3000, allowing the backplane substrate 3000 to be opposite to (e.g., face) the deposition mask 2000. For example, the substrate chuck 4300 may be an electrostatic chuck that holds the rear surface of the backplane substrate 3000 utilizing an electrostatic force. At this time, the electrode patterns AND and the pixel defining film PDL may be disposed or provided on the front surface of the backplane substrate 3000, and the substrate chuck 4300 may hold the rear surface of the backplane substrate 3000 such that the front surface of the backplane substrate 3000 is opposite to (e.g., faces) the deposition mask 2000.

A plurality of lift fingers 4400 to load the backplane substrate 3000 onto the substrate chuck 4300 may be disposed or provided in the process chamber 4100. The lift fingers 4400 may be disposed or provided around the substrate chuck 4300 and the mask stage 5000 and may be respectively moved vertically by finger drivers 4410. For example, three or four lift fingers 4400 may be disposed or provided around the substrate chuck 4300 and the mask stage 5000.

The backplane substrate 3000 may be loaded into the process chamber 4100 by a transfer robot and may be transferred from the transfer robot onto the lift fingers 4400 under the substrate chuck 4300. In one or more embodiments, the rear surface of the backplane substrate 3000 may be opposite to (e.g., face) the bottom surface of the substrate chuck 4300, and the lift fingers 4400 may support the front edge portions of the backplane substrate 3000. The finger drivers 4410 may raise the lift fingers 4400 such that the backplane substrate 3000 becomes adjacent to the bottom surface of the substrate chuck 4300 and, then, the rear surface of the backplane substrate 3000 may be held on the bottom surface of the substrate chuck 4300 by an electrostatic force.

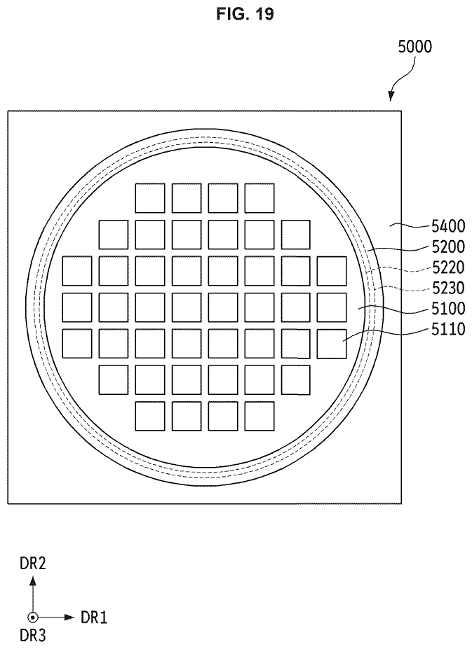

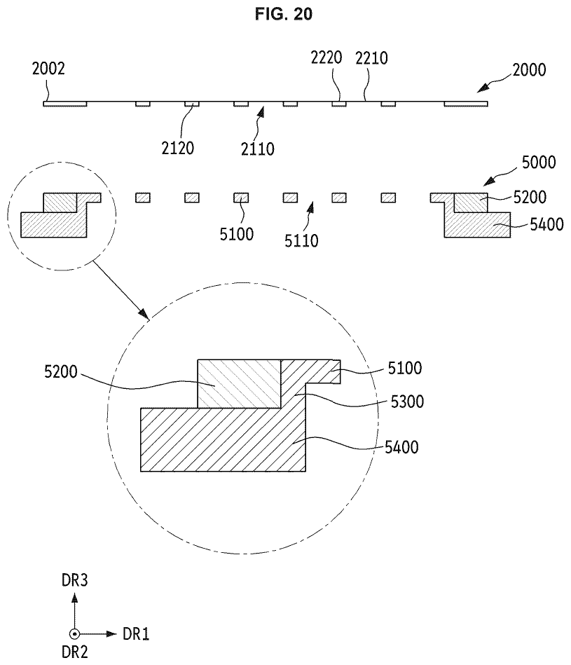

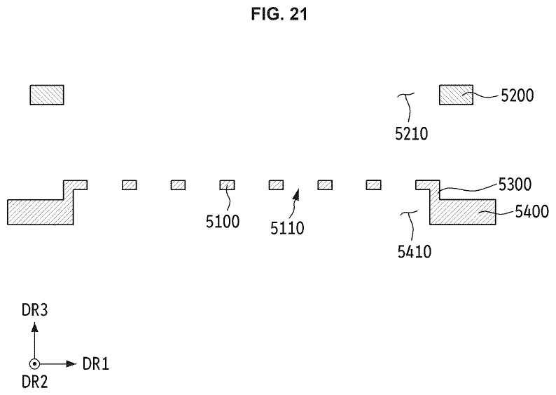

FIG. 19 is a schematic plan view illustrating the mask stage as illustrated in FIG. 14. FIGS. 20 and 21 are schematic cross-sectional views illustrating the mask stage as illustrated in FIG. 14.

Referring to FIGS. 19 to 21, the mask stage 5000 may include a lattice support 5100 that supports the deposition mask 2000 and has a plurality of lattice holes 5110 and a mask chuck 5200 that is configured or provided to be around (e.g., surround) the lattice support 5100 and supports an edge portion 2002 of the deposition mask 2000. For example, the lattice support 5100 may support the remaining portion of the deposition mask 2000 except for the edge portion 2002. For example, if (e.g., when) the deposition mask 2000 is placed or provided on the mask stage 5000, the cell openings 2110 of the deposition mask 2000 may communicate with the lattice holes 5110 of the lattice support 5100, and the lattice support 5100 may support the rib region 2120 of the deposition mask 2000.

The mask chuck 5200 may have a ring shape (e.g., a substantially ring shape) around (e.g., surrounding) the lattice support 5100. For example, the mask chuck 5200 may have a through hole 5210 into which the lattice support 5100 is inserted. For example, as illustrated, the mask chuck 5200 may have a circular ring shape (e.g., a substantially circular ring shape). In one or more embodiments, however, the mask chuck 5200 may have a disk shape (e.g., a substantially disk shape) or a quadrilateral plate shape (e.g., a substantially quadrilateral plate shape) having the through hole 5210 into which the lattice support 5100 is inserted.

The mask chuck 5200 may be an electrostatic chuck configured or provided to hold the edge portion 2002 of the deposition mask 2000 utilizing an electrostatic force. In one or more embodiments, the mask chuck 5200 may include an electrostatic electrode that provides the electrostatic force to hold the edge portion 2002 of the deposition mask 2000. For example, the mask chuck 5200 may include a first electrostatic electrode 5220 and a second electrostatic electrode 5230 to generate the electrostatic force. The first electrostatic electrode 5220 may have a circular ring shape (e.g., a substantially circular ring shape), and the second electrostatic electrode 5230 may have a circular ring shape (e.g., a substantially circular ring shape) around (e.g., surrounding) the first electrostatic electrode 5220.

The first electrostatic electrode 5220 and the second electrostatic electrode 5230 may be disposed or provided in a surface portion of the mask chuck 5200, and a first electrostatic voltage and a second electrostatic voltage may be applied to the first electrostatic electrode 5220 and the second electrostatic electrode 5230, respectively. For example, a positive voltage may be applied to the first electrostatic electrode 5220, and a negative voltage may be applied to the second electrostatic electrode 5230.

The mask chuck 5200 may be made of a ceramic material, such as aluminum oxide (e.g., Al₂O₃), aluminum nitride (e.g., AlN), yttrium oxide (e.g., Y₂O₃), and/or the like and may be manufactured by a pressure sintering process, for example. The first electrostatic electrode 5220 and the second electrostatic electrode 5230 may be made of a metal material, such as tungsten (W), molybdenum (Mo), titanium (Ti), and/or the like and may be formed or provided by a pressure sintering process, for example.

The lattice support 5100 may have a disk shape (e.g., a substantially disk shape) and may be inserted into the through hole 5210 of the mask chuck 5200. At this time, the top surface of the lattice support 5100 and the top surface of the mask chuck 5200 may be disposed or provided at substantially the same height so as to support the deposition mask 2000 in a flat manner (e.g., substantially in a flat manner). For example, the top surface of the lattice support 5100 may be processed to have a flatness of about 3 μm or less through a polishing process so as to support the deposition mask 2000 in a flat manner (e.g., substantially in a flat manner). In one or more embodiments, if (e.g., when) the thickness of the lattice support 5100 is excessively or substantially thin, for example, less than about 4 mm, deformation of the lattice support 5100 may occur during the polishing process, whereas if (e.g., when) the thickness of the lattice support 5100 is excessively or substantially thick, for example, exceeding about 6 mm, a shadow area may be generated on the backplane substrate 3000 due to the lattice support 5100 during the deposition process. Accordingly, the lattice support 5100 is desirable to have a thickness of about 5 mm to 6 mm.

The mask stage 5000 may include a base plate 5400 disposed or provided under the lattice support 5100 and a support ring 5300 disposed or provided between the lattice support 5100 and the base plate 5400 to support the lattice support 5100. The base plate 5400 may have an opening 5410 that exposes the lattice support 5100, and the support ring 5300 may be disposed or provided between the outer edge portion of the lattice support 5100 and the inner edge portion of the base plate 5400. In one or more embodiments, the mask chuck 5200 may be disposed or provided on the base plate 5400 to be around (e.g., surround) the lattice support 5100 and the support ring 5300. As illustrated, the base plate 5400 may have a quadrilateral plate shape (e.g., a substantially quadrilateral plate shape), but, in one or more embodiments, the base plate 5400 may have a disc shape (e.g., a substantially disc shape).

Referring again to FIG. 14, the deposition mask 2000 may be loaded into the process chamber 4100 by the transfer robot and may be transferred onto the lift fingers 4400 above the mask stage 5000. The edge portion 2002 of the deposition mask 2000 may be placed or provided on the ends of the lift fingers 4400, and the finger drivers 4410 may lower the lift fingers 4400 to load the deposition mask 2000 onto the mask stage 5000. In one or more embodiments, recesses into which the lift fingers 4400 are inserted may be provided at the edge portions of the top surface of the mask chuck 5200, and the finger drivers 4410 may rotate the lift fingers 4400 such that the lift fingers 4400 do not overlap the mask stage 5000 after the deposition mask 2000 is loaded or provided on the mask stage 5000.

The deposition apparatus 4000 may include a substrate chuck driver 4500 to move the substrate chuck 4300 and a stage driver 4600 to move the mask stage 5000. For example, the substrate chuck driver 4500 may move the substrate chuck 4300 in the first direction DR1, the second direction DR2, and the third direction DR3 to adjust the position of the backplane substrate 3000. In one or more embodiments, the first direction DR1 may be the first horizontal direction, the second direction DR2 may be the second horizontal direction perpendicular (e.g., substantially perpendicular) to the first direction DR1, and the third direction DR3 may be the vertical direction. For example, the first direction DR1, the second direction DR2, and the third direction DR3 may be an X-axis direction, a Y-axis direction, and a Z-axis direction, respectively.

The substrate chuck driver 4500 may rotate the substrate chuck 4300 around the Z-axis in order to adjust the azimuth of the backplane substrate 3000. Further, the substrate chuck driver 4500 may rotate the substrate chuck 4300 around the X-axis and may also rotate the substrate chuck 4300 around the Y-axis in order to adjust the inclination of the backplane substrate 3000. For example, the substrate chuck driver 4500 may include a hexapod actuator that provides a motion of 6 degrees of freedom (e.g., X, Y, Z, θₓ, θ_{y}, and θ_{z}).

The deposition apparatus 4000 may include a movable plate 4710 on which the substrate chuck driver 4500 is mounted and a vertical driver 4700 connected to the movable plate 4710. The movable plate 4710 may be disposed or provided horizontally (e.g., substantially horizontally) in the process chamber 4100, and the vertical driver 4700 may be disposed or provided above the process chamber 4100. The vertical driver 4700 may be connected to the movable plate 4710 by a plurality of drive shafts 4720 that extend in the third direction DR3, e.g., a vertical direction (Z-axis direction) through an upper lid of the process chamber 4100, and may move the movable plate 4710 in the direction of the central axis of the substrate chuck driver 4500, e.g., in the vertical direction. For example, the vertical driver 4700 may be configured or provided by utilizing a brushless DC motor, a linear motor, a direct drive (DD) motor, and/or the like and may adjust the height of the substrate chuck 4300 to load or unload the backplane substrate 3000.

The substrate chuck driver 4500 may include a first platform 4510 connected to the substrate chuck 4300, a second platform 4520 mounted on the movable plate 4710, and six sub-actuators 4530 disposed or provided between the first platform 4510 and the second platform 4520. The six sub-actuators 4530 may move and rotate the first platform 4510 to adjust the horizontal position of the backplane substrate 3000, the vertical position of the backplane substrate 3000, the azimuth of the backplane substrate 3000, and the inclination of the backplane substrate 3000. For example, the six sub-actuators 4530 may each be configured or provided by utilizing a brushless DC motor, a voice coil linear motor, a step motor, a direct drive (DD) motor, a servo motor, and/or the like.

The stage driver 4600 may move and rotate the mask stage 5000 to adjust the horizontal position of the deposition mask 2000 and the azimuth of the deposition mask 2000. The stage driver 4600 may move the mask stage 5000 in a direction parallel (e.g., substantially parallel) to the deposition mask 2000 and rotate the mask stage 5000 with respect to the central axis of the mask stage 5000. For example, the stage driver 4600 may move the mask stage 5000 in the first direction DR1 (X-axis) and the second direction DR2 (Y-axis) and may rotate the mask stage 5000 with respect to the third direction DR3 (Z-axis).

The stage driver 4600 may include a piezo actuator that provides a motion of three degrees of freedom (X, Y, and θ_{z}). The piezo actuator may have a circular ring shape (e.g., a substantially circular ring shape) or a quadrilateral ring shape (e.g., a substantially quadrilateral ring shape), and the mask stage 5000 may be disposed or provided on the piezo actuator. The deposition apparatus 4000 may include a support plate 4610 horizontally (e.g., substantially horizontally) disposed or provided in the process chamber 4100 to support the stage driver 4600. For example, the support plate 4610 may have an opening to expose the deposition mask 2000 toward the deposition source 4200 and may be supported by a plurality of posts 4620 connected to the upper lid of the process chamber 4100. Because, however, the support structure of the support plate 4610 may be suitably changed, the scope of the present disclosure is not limited thereby.

After the backplane substrate 3000 and the deposition mask 2000 are loaded onto the substrate chuck 4300 and the mask stage 5000, the vertical driver 4700 may lower the substrate chuck 4300 to a preset (e.g., set or predetermined) height, and the substrate chuck driver 4500 may adjust the inclination of the substrate chuck 4300 to adjust the parallelism between the substrate chuck 4300 and the mask stage 5000. For example, in one or more embodiments, a plurality of gap sensors to measure the gap between the substrate chuck 4300 and the mask chuck 5200 may be mounted on the substrate chuck 4300, and the substrate chuck driver 4500 may adjust the parallelism between the substrate chuck 4300 and the mask stage 5000 based on measurement values of the gap sensors.

In one or more embodiments, the substrate chuck driver 4500 and/or the stage driver 4600 may perform alignment between the backplane substrate 3000 and the deposition mask 2000. For example, in one or more embodiments, a plurality of substrate alignment keys may be arranged or provided on the edge portion of the backplane substrate 3000, and a plurality of mask alignment keys that correspond to the plurality of substrate alignment keys may be arranged or provided on the edge portion 2002 of the deposition mask 2000. The deposition apparatus 4000 may include a camera unit to detect the substrate alignment key and the mask alignment key, and an illumination unit to illuminate the substrate alignment key and the mask alignment key, and the substrate chuck 4300 and/or the mask stage 5000 may be provided with through holes to provide illumination light and detect the substrate alignment key and the mask alignment key.

For example, the illumination unit may provide near infrared (NIR) and/or short wave infrared (SWIR) light, e.g., infrared light having a wavelength of about 1010 nm to about 1020 nm, and the camera unit may detect infrared light transmitted through the backplane substrate 3000 and the deposition mask 2000. The substrate chuck driver 4500 or the stage driver 4600 may perform positional alignment between the backplane substrate 3000 and the deposition mask 2000 based on positional information of the substrate alignment key and the mask alignment key acquired by the camera unit.

As described in one or more embodiments, after the parallelism adjustment between the substrate chuck 4300 and the mask stage 5000 and the positional alignment between the backplane substrate 3000 and the deposition mask 2000 are performed, the backplane substrate 3000 may be positioned or provided on the deposition mask 2000. For example, the substrate chuck driver 4500 may adjust the height of the substrate chuck 4300 such that the gap between the backplane substrate 3000 and the deposition mask 2000 becomes a preset (e.g., set or predetermined) gap, e.g., a gap of several μm. For another example, the substrate chuck driver 4500 may adjust the height of the substrate chuck 4300 such that the backplane substrate 3000 is brought into contact with the deposition mask 2000.

After the backplane substrate 3000 is positioned or provided on the deposition mask 2000, the deposition source 4200 may provide a vapor deposition material onto the backplane substrate 3000 through the deposition mask 2000, thereby forming or providing a deposition material layer on the backplane substrate 3000. For example, the deposition source 4200 may evaporate an organic material to form or provide light emitting material layers on the backplane substrate 3000, and the evaporated organic material may be deposited on the electrode patterns AND of the backplane substrate 3000 through the pixel openings 2212 of the deposition mask 2000.

According to one or more embodiments of the present disclosure, the deposition mask 2000 may be made of a non-magnetic material. For example, as described in one or more embodiments, the deposition mask 2000 may include a silicon substrate that functions as the mask frame 2100, the membrane 2200 made of silicon nitride (e.g., Si₃N₄ or SiNₓ, wherein 0<X≤2), and the rear inorganic film 2300. The lattice support 5100 of the mask stage 5000 may be made of a ferromagnetic material, and a magnetic force source 4800 to apply a magnetic force to the lattice support 5100 may be disposed or provided above the substrate chuck 4300. In one or more embodiments, the magnetic force source 4800 may apply a magnetic force to the lattice support 5100 in a direction toward the substrate chuck 4300, and, accordingly, the deposition mask 2000 may be sufficiently or suitably brought into close contact with the backplane substrate 3000 between the substrate chuck 4300 and the lattice support 5100.

For example, the lattice support 5100 may be made of ferritic stainless steel, such as STS409, STS430, STS439, and/or the like, martensitic stainless steel, such as STS410, STS420, STS440, and/or the like, precipitation hardening stainless steel, such as STS630, STS631, and/or the like, and/or an invar alloy including iron (Fe) and/or nickel (Ni). In one or more embodiments, however, the lattice support 5100 may be made of materials other than the materials as described in one or more embodiments, and, thus, it should be noted that the scope of the present disclosure is not limited by the materials that form or provide the lattice support 5100.

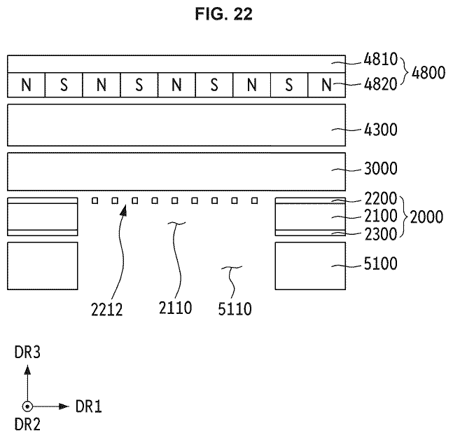

FIG. 22 is a schematic enlarged cross-sectional view illustrating the magnetic force source and the lattice support illustrated in FIG. 14.

Referring to FIG. 22, the magnetic force source 4800 may include a yoke plate 4810 and a plurality of permanent magnets 4820 mounted on the bottom surface of the yoke plate 4810. The plurality of permanent magnets 4820 may be arranged or provided in a matrix form along the first direction DR1 and the second direction DR2, and the polarities of these permanent magnets 4820 may alternate in the first direction DR1 and the second direction DR2. According to one or more embodiments of the present disclosure, the magnetic force source 4800 may be disposed or provided above the substrate chuck 4300 and may be configured or provided to be movable in the third direction DR3, e.g., in the vertical direction, by a second driver 4900 as illustrated in FIG. 14.

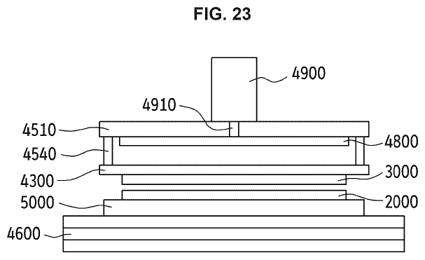

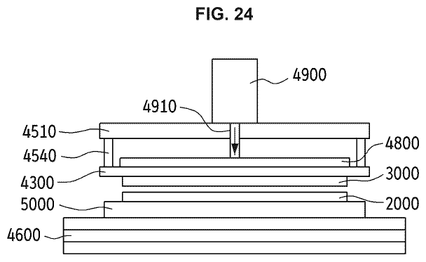

FIGS. 23 and 24 are schematic side views illustrating the second driver as illustrated in FIG. 14.

Referring to FIGS. 23 and 24, the substrate chuck 4300 may be spaced and/or apart (e.g., spaced apart or separated) from the first platform 4510 of the substrate chuck driver 4500 in the third direction DR3, and the substrate chuck driver 4500 may include a plurality of connection members 4540 that connect the first platform 4510 to the substrate chuck 4300. The magnetic force source 4800 may be disposed or provided between the substrate chuck 4300 and the first platform 4510 of the substrate chuck driver 4500, and the second driver 4900 may be disposed or provided on the first platform 4510 of the substrate chuck driver 4500. By way of example, the second driver 4900 may be configured or provided by utilizing a brushless DC motor, a linear motor, a direct drive (DD) motor, and/or the like and may include a drive shaft 4910 that penetrates the first platform 4510 of the substrate chuck driver 4500 to be connected to the yoke plate 4810 of the magnetic force source 4800.

The second driver 4900 may move the magnetic force source 4800 in the third direction DR3 between the substrate chuck 4300 and the first platform 4510 of the substrate chuck driver 4500. For example, the second driver 4900 may move the magnetic force source 4800 in the third direction DR3 to adjust the gap between the substrate chuck 4300 and the magnetic force source 4800. For example, after the backplane substrate 3000 may be positioned or provided on the deposition mask 2000 by the substrate chuck driver 4500, the second driver 4900 may lower the magnetic force source 4800 such that the magnetic force source 4800 is adjacent to the top surface of the substrate chuck 4300, for example, such that the magnetic force source 4800 is placed or provided on the top surface of the substrate chuck 4300, as illustrated in FIG. 24. Accordingly, a magnetic force may be applied from the permanent magnets 4820 of the magnetic force source 4800 to the lattice support 5100 in the third direction DR3. As a result, the deposition mask 2000 may be sufficiently or suitably brought into close contact with the backplane substrate 3000 by the magnetic force, and the deposition mask 2000 may prevent or reduce sagging down due to its own weight while the deposition process is being performed. Upon the completion of the deposition process, the second driver 4900 may raise the magnetic force source 4800 such that the magnetic force source 4800 is spaced and/or apart (e.g., spaced apart or separated) from the substrate chuck 4300, and, as a result, the magnetic force applied from the magnetic force source 4800 to the lattice support 5100 may be removed or reduced.

According to one or more embodiments of the present disclosure, while the deposition process is being performed, the deposition mask 2000 may be supported by the lattice support 5100 and may be sufficiently or suitably brought into close contact with the backplane substrate 3000 by the magnetic force source 4800. As a result, the pixel position accuracy (PPA) of the deposition material layers formed or provided on the backplane substrate 3000 may be improved or enhanced, and the color mixing phenomenon between the sub-pixels SP1, SP2, and SP3 may be reduced.

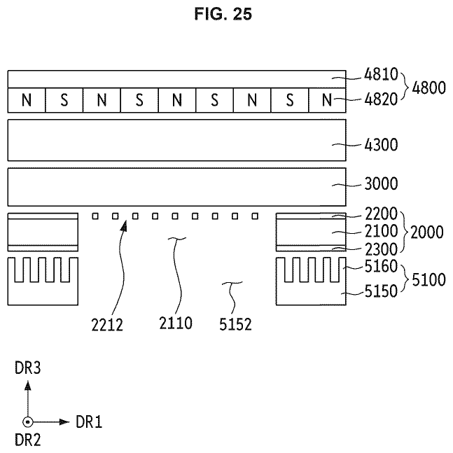

FIG. 25 is a schematic enlarged cross-sectional view illustrating another example of the lattice support as illustrated in FIG. 22.

Referring to FIG. 25, the lattice support 5100 may include a lattice plate 5150 having lattice holes 5152, and a plurality of protrusions 5160 disposed or provided on the lattice plate 5150. The plurality of protrusions 5160 may be used to allow the magnetic force of the magnetic force source 4800 to be uniformly (e.g., substantially uniformly) applied to the lattice support 5100 from the permanent magnets 4820. For example, the plurality of protrusions 5160 may have a pillar shape (e.g., a substantially pillar shape) that extends in the third direction DR3 and may be arranged or provided in a matrix form along the first direction DR1 and the second direction DR2. As another example, the plurality of protrusions 5160 may extend along the first direction DR1 and be arranged or provided in the second direction DR2. As another example, the plurality of protrusions 5160 may extend along the second direction DR2 and be arranged or provided in the first direction DR1.

The magnetic force provided from the magnetic force source 4800 may be applied more uniformly to the lattice support 5100 due to the plurality of protrusions 5160, and, accordingly, the force applied from the lattice support 5100 to the deposition mask 2000 may be distributed in a more uniform manner. As a result, the gap between the backplane substrate 3000 and the deposition mask 2000 may be made constant (e.g., substantially constant), and the pixel position accuracy (PPA) of the deposition material layers formed or provided on the backplane substrate 3000 may be thus improved or enhanced.

The subject matter of the present disclosure should not be construed as being limited to one or more embodiments set forth herein. Rather, these embodiments are provided as examples so that this disclosure will be thorough and complete and will fully convey the aspects and features of embodiments of the present disclosure to those skilled in the art.

While the subject matter of the present disclosure has been described with reference to the drawings, it will be understood by those of ordinary skill in the art that one or more suitable changes in form and more details may be made therein without departing from the spirit and scope as defined by the appended claims and equivalents thereof.

What is claimed is:

1. A mask stage, comprising:
a lattice support supporting a deposition mask and having a plurality of lattice holes; and
a mask chuck around the lattice support and supporting an edge portion of the deposition mask,
wherein the deposition mask is made of a non-magnetic material, and the lattice support is made of a ferromagnetic material.

2. The mask stage as claimed in claim 1, wherein the deposition mask comprises:
a mask frame having a plurality of cell openings and comprising a rib region defining the plurality of cell openings; and
a membrane having a plurality of pixel openings to communicate with the plurality of cell openings and provided on the mask frame.

3. The mask stage as claimed in claim 2, wherein the lattice support supports the rib region, and the plurality of lattice holes communicate with the plurality of cell openings.

4. The mask stage as claimed in claim 3, wherein the lattice support comprises a plurality of protrusions, and
the rib region is supported by the plurality of protrusions.

5. The mask stage as claimed in claim 1, wherein the lattice support is made of ferritic stainless steel, martensitic stainless steel, precipitation hardening stainless steel, or an invar alloy.

6. The mask stage as claimed in claim 1, wherein the mask chuck comprises an electrostatic electrode to provide an electrostatic force to hold the edge portion of the deposition mask.

7. A deposition apparatus, comprising:
a deposition source to provide a vapor deposition material;
a mask stage above the deposition source and on which a deposition mask is placed; and
a substrate chuck above the mask stage and supporting a substrate to be opposite to the deposition mask,
wherein the mask stage comprises:
a lattice support supporting the deposition mask and having a plurality of lattice holes; and
a mask chuck around the lattice support and supporting an edge portion of the deposition mask,
wherein the deposition mask is made of a non-magnetic material, and the lattice support is made of a ferromagnetic material.

8. The deposition apparatus as claimed in claim 7, further comprising a magnetic force source above the substrate chuck and provided to apply a magnetic force to the lattice support.

9. The deposition apparatus as claimed in claim 8, wherein the magnetic force source comprises:
a yoke plate; and
a plurality of permanent magnets mounted on a bottom surface of the yoke plate.

10. The deposition apparatus as claimed in claim 8, further comprising a substrate chuck driver to move the substrate chuck in horizontal and vertical directions.

11. The deposition apparatus as claimed in claim 10, wherein the substrate chuck is spaced apart from the substrate chuck driver and connected to the substrate chuck driver by a plurality of connection members, and
the magnetic force source is between the substrate chuck and the substrate chuck driver.

12. The deposition apparatus as claimed in claim 10, wherein the substrate chuck driver comprises:
a first platform connected to the substrate chuck;
a second platform above the first platform; and
six sub-actuators between the first platform and the second platform.

13. The deposition apparatus as claimed in claim 8, further comprising a second driver to move the magnetic force source to adjust a gap between the substrate chuck and the magnetic force source.

14. The deposition apparatus as claimed in claim 8, further comprising:
a substrate chuck driver to move the substrate chuck to adjust a position of the substrate chuck; and
a second driver to move the magnetic force source to adjust a position of the magnetic force source,
wherein after the substrate is positioned on the deposition mask by the substrate chuck driver, the magnetic force source is positioned adjacent to a top surface of the substrate chuck by the second driver.

15. The deposition apparatus as claimed in claim 7, wherein the deposition mask comprises:
a mask frame having a plurality of cell openings and comprising a rib region defining the plurality of cell openings; and
a membrane having a plurality of pixel openings to communicate with the plurality of cell openings and provided on the mask frame.

16. The deposition apparatus as claimed in claim 15, wherein the lattice support supports the rib region, and the plurality of lattice holes communicate with the plurality of cell openings.

17. The deposition apparatus as claimed in claim 16, wherein the lattice support comprises a plurality of protrusions, and
the rib region is supported by the plurality of protrusions.

18. The deposition apparatus as claimed in claim 7, wherein the lattice support comprises:
a lattice plate having the plurality of lattice holes; and
a plurality of protrusions on the lattice plate,
wherein the deposition mask is supported by the plurality of protrusions.

19. The deposition apparatus as claimed in claim 7, wherein the lattice support is made of ferritic stainless steel, martensitic stainless steel, precipitation hardening stainless steel, or an invar alloy.

20. An electronic device comprising a display panel,
wherein the display panel comprises a substrate and light emitting layers provided on the substrate utilizing a deposition mask and a mask stage supporting the deposition mask,
the mask stage comprises:
a lattice support supporting the deposition mask and having a plurality of lattice holes; and
a mask chuck around the lattice support and supporting an edge portion of the deposition mask, and
the deposition mask is made of a non-magnetic material, and the lattice support is made of a ferromagnetic material.
